(19) United States
(12) Patent Application Publication
(10) Pub. No.: US 2026/0314045 A1
(43) Pub. Date: Oct. 8, 2026

(54) SEMICONDUCTOR DEVICE AND METHODS OF FORMING THE SAME

(71) Applicant: TAIWAN SEMICONDUCTOR MANUFACTURING COMPANY, LTD., Hsinchu (TW)

(72) Inventors: Chia-Ao CHANG, Kinmen (TW); Hsueh-Chang SUNG, Hsinchu (TW); Chien-Chia CHENG, Hsinchu (TW); Ming-Hua YU, Hsinchu (TW)

(21) Appl. No.: 19/170,331

(22) Filed: Apr. 4, 2025

(51) Int. Cl. H10D 84/83; H10D 30/00; H10D 30/01; H10D 30/43; H10D 62/10; H10D 62/13; H10D 64/01; H10D 64/27; H10D 84/01

(52) U.S. Cl. CPC H10D 84/832; H10D 30/014; H10D 30/0191; H10D 30/43; H10D 30/502; H10D 62/102; H10D 62/121; H10D 62/151; H10D 64/017; H10D 64/518; H10D 84/0135; H10D 84/0144; H10D 84/83125

(57) ABSTRACT

Embodiments of the present disclosure provide a semiconductor device. The semiconductor device includes a gate electrode disposed over a channel region and epitaxial source/drain features interposing the channel region in a first direction. The gate electrode has a longitudinal axis extending in a second direction and includes a lower portion and an upper portion over the lower portion. The gate electrode includes a sidewall extending along the first direction. The sidewall includes a major surface, first protrusions protruding over the major surface in the lower portion of the gate electrode, and second protrusions protruding over the major surface in the upper portion of the gate electrode. The major surface is a flat surface, and a density of the first protrusions in the lower portion of the gate electrode is less than a density of the second protrusions in the upper portion of the gate electrode.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 5 are perspective views of intermediate stages of manufacturing a semiconductor device, in accordance with some embodiments.

FIGS. 6 to 8C and 10A to 20D are cross-sectional views of intermediate stages of manufacturing a semiconductor device, in accordance with some embodiments.

FIG. 9 illustrates a process flow chart of manufacturing a dummy gate electrode in the semiconductor device, in accordance with some embodiments.

FIGS. 21A to 22D are cross-sectional views of intermediate stages of manufacturing a semiconductor device, in accordance with some embodiments.

FIG. 23 illustrates a process flow chart of manufacturing a dummy gate electrode in the semiconductor device, in accordance with some embodiments.

FIGS. 24A to 26D are cross-sectional views of intermediate stages of manufacturing a semiconductor device, in accordance with some embodiments.

FIG. 27 illustrates a process flow chart of manufacturing a dummy gate electrode in the semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a semiconductor device and methods for manufacturing it. The method includes forming a dummy gate layer over semiconductor strips. The dummy gate layer has different crystalline particles in its lower portion and upper portion. Accordingly, the dummy gate layer may generate less stress to the semiconductor strips underlying the dummy gate layer, which may reduce the risks that the semiconductor strips being bent and damaged resulting from the formation of the dummy gate layer. In addition, the crystalline particles may generate protrusions on the sidewalls, which may create more space for fill in replacement gate electrodes when the gate electrodes have a given pitch.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning, or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

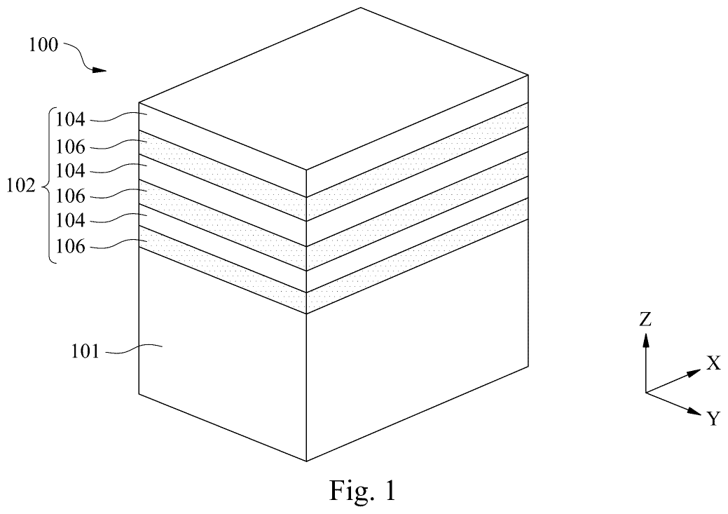

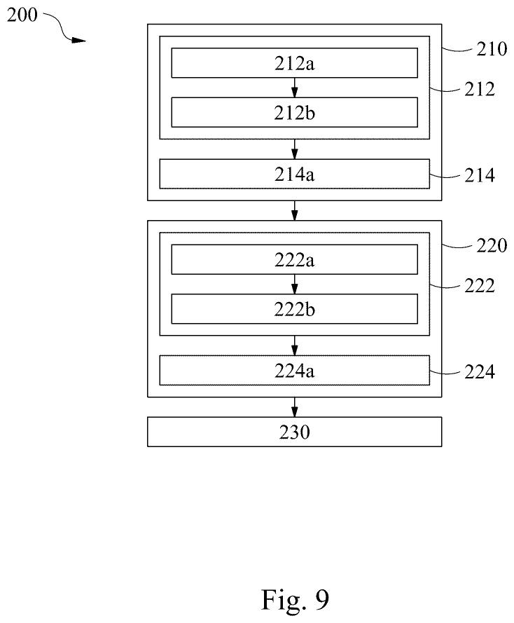

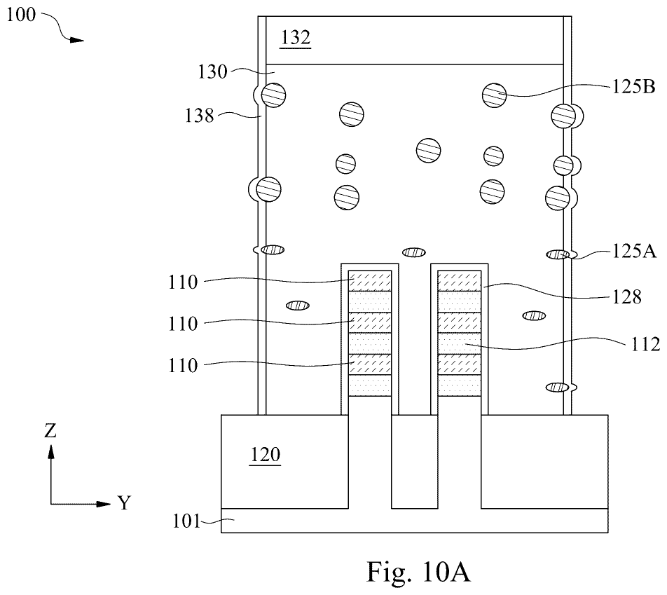

FIGS. 1-8C and 10A-20D show exemplary processes for manufacturing a semiconductor device 100 according to embodiments of the present disclosure. FIG. 9 illustrates a flow chart of manufacturing the dummy gate layer of the semiconductor device 100, in accordance with some embodiments. It is understood that additional operations can be provided before, during, and after processes shown by FIGS. 1-8C and 10A-20D, and some of the operations described below can be replaced or eliminated, for additional embodiments of the method. The order of the operations/processes is not limiting and may be interchangeable.

FIGS. 1-5 are perspective views of intermediate stages in manufacturing a semiconductor device 100, in accordance with some embodiments. The semiconductor device 100 also includes a multilayer stack 102 formed over the substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. The substrate 101 may include various regions that have been doped with impurities (e.g., dopants having p-type or n-type conductivity) in the substrate 101.

The multilayer stack 102 includes alternating semiconductor layers made of different materials to facilitate the formation of nanostructure channels in a multi-gate device, such as nanostructure channel FETs. In some embodiments, the multilayer stack 102 includes first semiconductor layers 104 and second semiconductor layers 106 that are alternately stacked over the substrate 101. For example, the multilayer stack 102 is illustrated as including three layers of first semiconductor layers 104 and three layers of second semiconductor layers 106 for illustrative purposes. It is appreciated that any number of the first and second semiconductor layers 104, 106 can be included in the multilayer stack 102. In some embodiments, the first semiconductor layers 104 are formed of a first semiconductor material, and the second semiconductor layers 106 are formed of a second semiconductor material different from the first semiconductor material. The second semiconductor material may have a different etch selectively and/or oxidation rate than the first semiconductor material. In some embodiments, either the first semiconductor material or the second semiconductor material is or includes a material such as SiGe, SiC, GeAs, GaP, InP, InAs, InSb, GaAsP, AlInAs, AlGaAs, InGaAs, GaInP, GaInAsP, combinations thereof, or the like. In some embodiments, the first semiconductor material is formed of Si, and the second semiconductor material is formed of SiGe, or vice versa.

Each first semiconductor layer 104 may have a thickness in a range between about nm and about 30 nm. Each second semiconductor layer 106 may have a thickness that is equal, less, or greater than the thickness of the first semiconductor layer 104. In some embodiments, each second semiconductor layer 106 has a thickness in a range between about 2 nm and about 50 nm. The first and second semiconductor layers 104, 106 are formed by any suitable deposition process, such as epitaxy deposition. By way of example, the epitaxial deposition of the multilayer stack 102 may be performed by vapor-phase epitaxy (VPE), molecular beam epitaxy (MBE), chemical vapor deposition (CVD), low-pressure metalorganic chemical vapor deposition (MOCVD) process, atomic layer deposition (ALD), the like, and/or other suitable epitaxial growth processes.

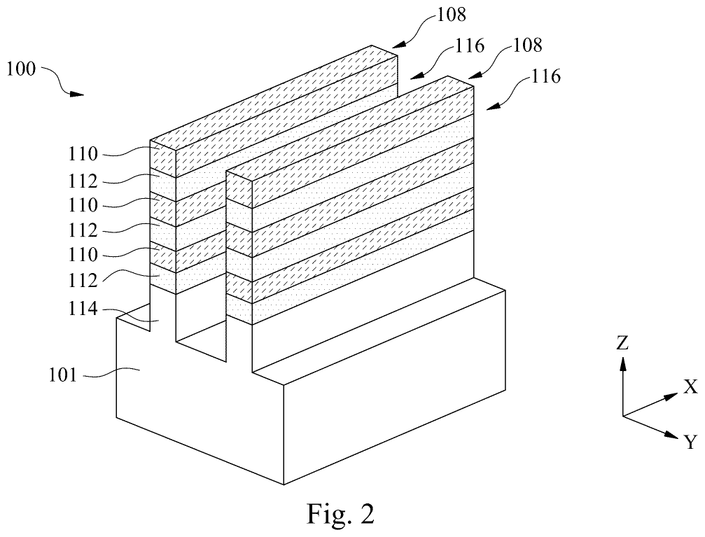

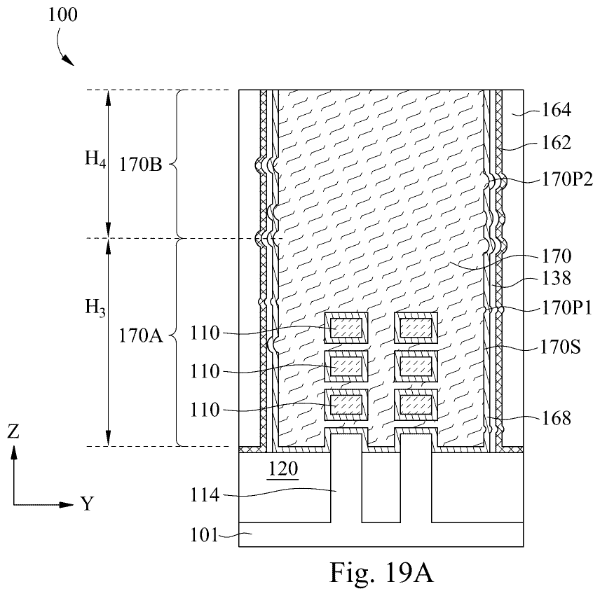

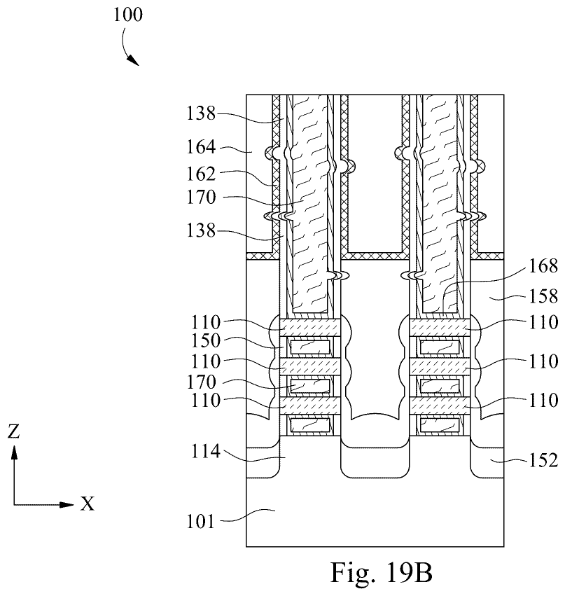

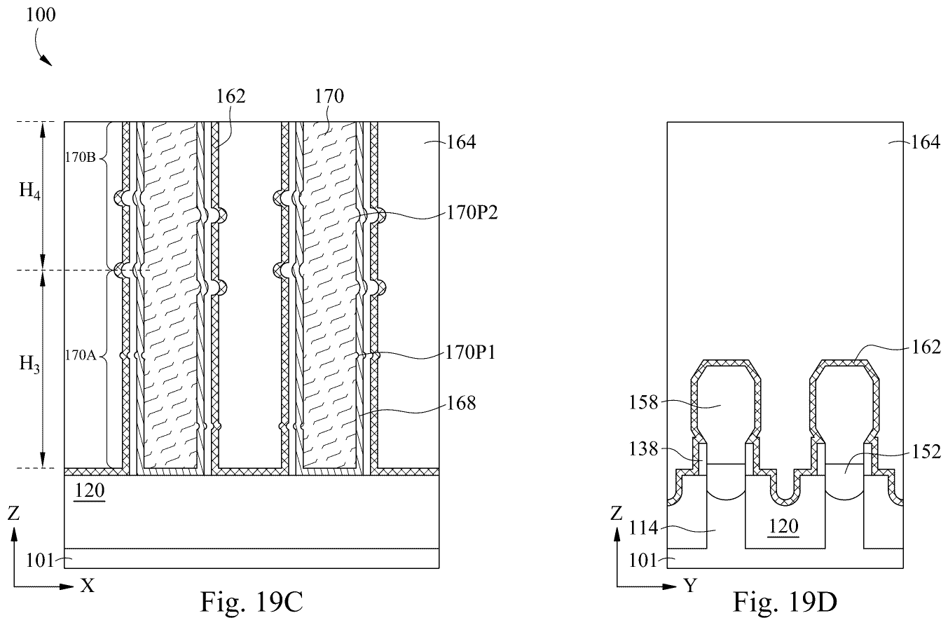

In FIG. 2, the multilayer stack 102 and the substrate 101 are patterned by one or more etch processes to form semiconductor strips 108, in accordance with some embodiments. Each semiconductor strip 108 may include first nanostructures 110 patterned from the first semiconductor layers 104 and second nanostructures 112 patterned from the second semiconductor layers 106. The substrate 101 may include a plurality of fins 114 after the etch processes. The semiconductor strips 108 are disposed over the fins 114, respectively. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. In embodiments as illustrated in the following Figures, the first nanostructures 110 may act as the channel regions of the semiconductor device 100, and second nanostructures 112 may be replaced with gate electrodes 170 (FIGS. 19A-D). However, it is appreciated that, in some embodiments, the second nanostructures 112 may act as the channel regions of the semiconductor device 100, and the first nanostructures may be replaced with gate electrodes 170.

The semiconductor strips 108 may be formed by patterning a hard mask layer (not shown) formed on the multilayer stack 102 using multi-patterning operations that include lithography and etch processes. The etch process can include dry etching such as reactive ion etching (RIE) or neutral beam etching (NBE), wet etching, and/or other suitable processes. The lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etch process forms trenches 116 in unprotected regions through the hard mask layer, through the multilayer stack 102, and into the substrate 101, thereby leaving the semiconductor strips 108 and the fins 114. The trenches 116 extend along the X direction. In some embodiments, the semiconductor strips 108 and the fins 114 have a longitudinal axis along the X direction.

The semiconductor device 100 may include a plurality of transistor structures. The first nanostructures 110 or portions thereof may form nanostructure channel(s) of the transistor structures in later fabrication stages, while the second nanostructures 112 may act as sacrificial layers in later fabrication stages for allowing the nanostructure channel(s) to be surrounded by gate structures. The transistor structures having the nanostructure channel(s) may be referred to as nanostructure transistors, nanosheet transistors, nanowire transistors, gate-all-around (GAA) transistors, multi-bridge channel (MBC) transistors, or any transistors having gate electrodes surrounding channels.

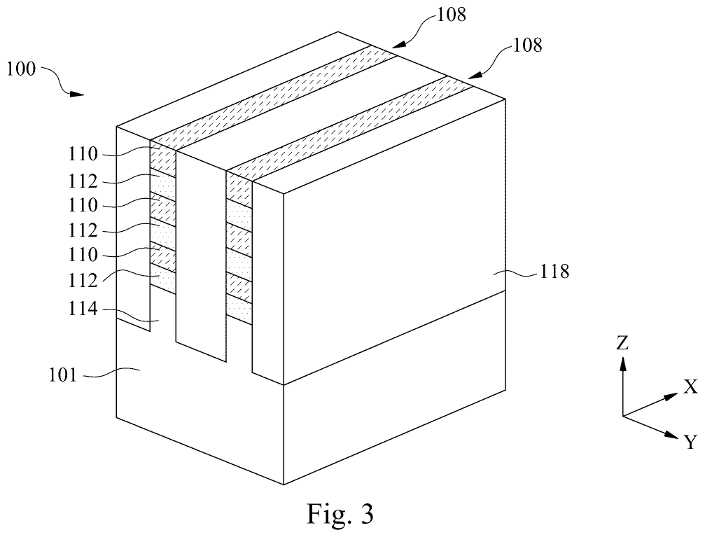

In FIG. 3, after the semiconductor strips 108 are formed, an insulating material 118 is formed over the substrate 101, in accordance with some embodiments. The insulating material 118 fills the trenches 116 between neighboring semiconductor strips 108 until the semiconductor strips 108 are embedded in the insulating material 118. Then, a planarization operation, such as a chemical mechanical polishing (CMP) method and/or an etch-back method, is performed such that the top of the semiconductor strips 108 is exposed. The insulating material 118 may be made of silicon oxide, silicon nitride, silicon oxynitride (SiON), silicon oxycarbonitride (SiOCN), silicon carbonitride (SiCN), fluorine-doped silicate glass (FSG), a low-K dielectric material (dielectric constant less than about 3.5), or any suitable dielectric material. The insulating material 118 may be formed by any suitable method, such as flowable CVD (FCVD), low-pressure chemical vapor deposition (LPCVD), or plasma-enhanced CVD (PECVD).

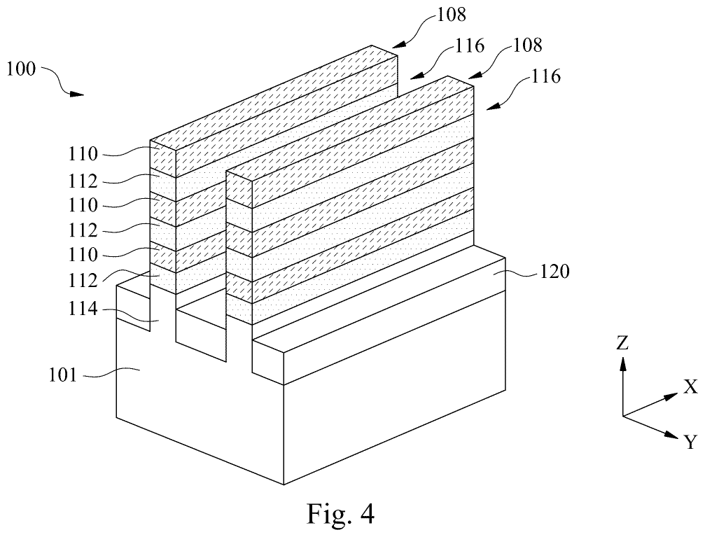

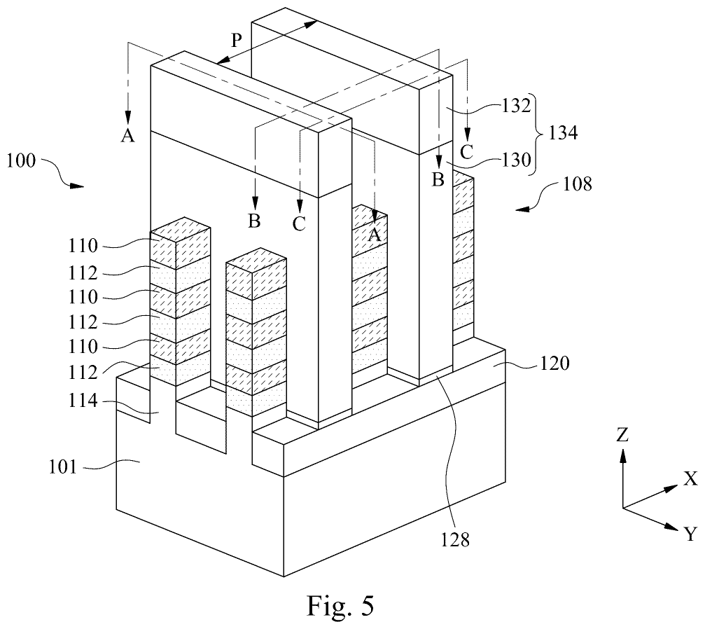

In FIG. 4, the insulating material 118 is recessed to form shallow trench isolation (STI) regions 120, in accordance with some embodiments. The recess of the insulating material 118 exposes portions of the semiconductor strips 108 and the substrate 101. The recess of the insulating material 118 reveals the trenches 116 between the neighboring semiconductor strips 108. The STI regions 120 may be formed using a suitable process, such as a dry etch process, a wet etch process, or a combination thereof. Top surfaces of the STI regions 120 may be level with or below top surfaces of the fins 114 and in contact with the fins 114. In FIG. 5, dummy gate dielectrics 128 and dummy gate electrodes 130 (collectively dummy gate structures 134) are formed over the semiconductor device 100, such as disposed over the semiconductor strips 108 in accordance with some embodiments.

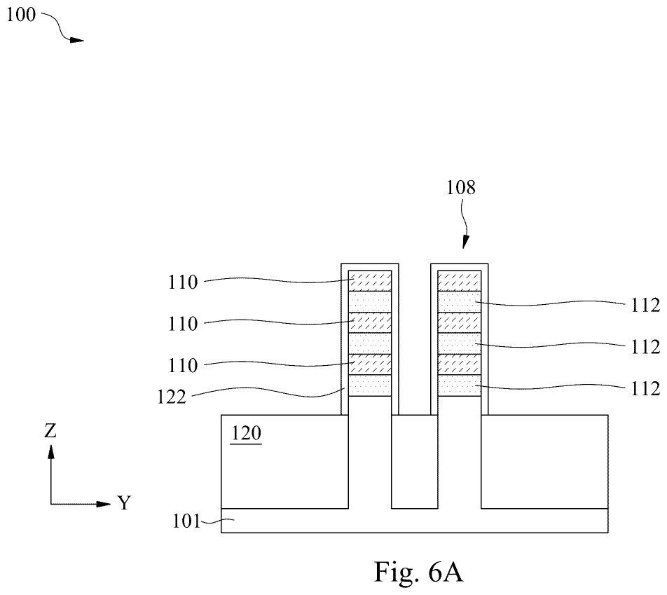

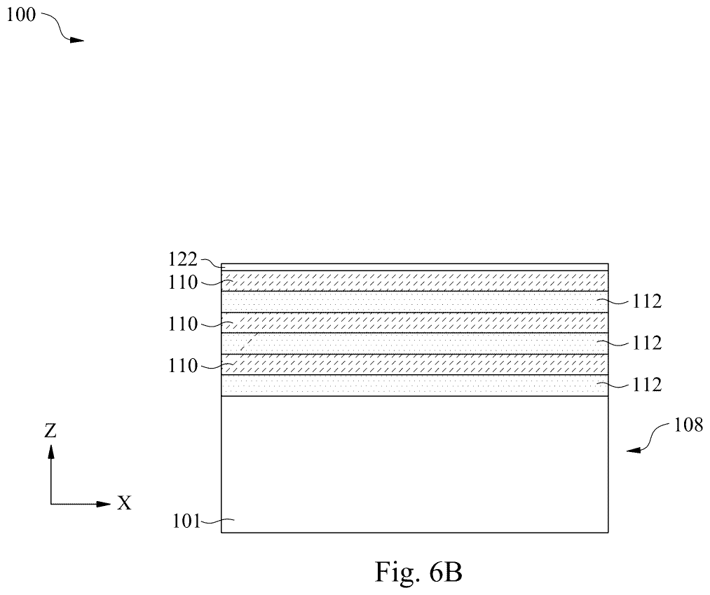

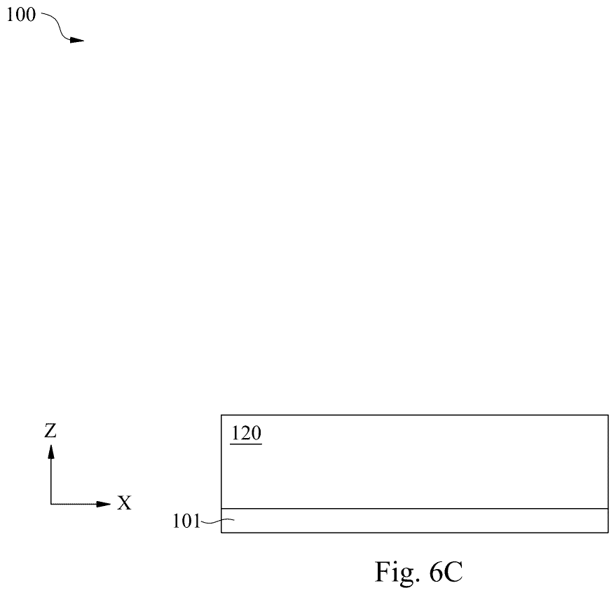

The dummy gate electrodes 130 may have a longitudinal direction (e.g., the Y-direction in FIG. 5) substantially perpendicular to the longitudinal directions of the semiconductor strips 108 (e.g., the X-direction in FIG. 5). The dummy gate electrodes 130 may land on the STI regions 120. The dummy gate dielectrics 128 and the dummy gate electrodes 130 are formed by multiple steps. In some embodiments, each dummy gate electrode 130 crosses over a single one or a plurality of the semiconductor strips 108. FIGS. 6A-8C are cross-sectional views illustrating the formation of the dummy gate dielectrics 128 and the dummy gate electrodes 130. Through the application, Figures with figure number including “A” are figures taken along section A-A illustrated in FIG. 5; Figures with figure number including “B” are figures taken along section B-B illustrated in FIG. 5; Figures with figure number including “C” are figures taken along section C-C illustrated in FIG. 5; and Figures with figure number including “D” are figures taken along section D-D illustrated in FIG. 5. In some embodiments, the dummy gate electrodes 130 are formed using the flow 200 as illustrated in FIG. 9. The neighboring dummy gate electrodes 130 may have a pitch P of about 10 nm to about 100 nm.

In FIGS. 6A-6C, a dielectric layer 122 is formed over the semiconductor device 100, such as formed over the semiconductor strips 108. The dielectric layer 122 may include silicon oxide, silicon oxynitride, or a combination thereof. The dielectric layer 122 may be selectively grown on the semiconductor strips 108 by oxidizing the semiconductor strips 108 using oxygen, water, water steam, ozone, nitric acid, sulfuric acid, or other suitable oxidization agents, and with an optional anneal process after the oxidation. Alternatively, the dielectric layer 122 may be a blanket layer formed by a suitable deposition process, such as chemical vapor deposition (CVD), atomic layer deposition (ALD), or a combination thereof.

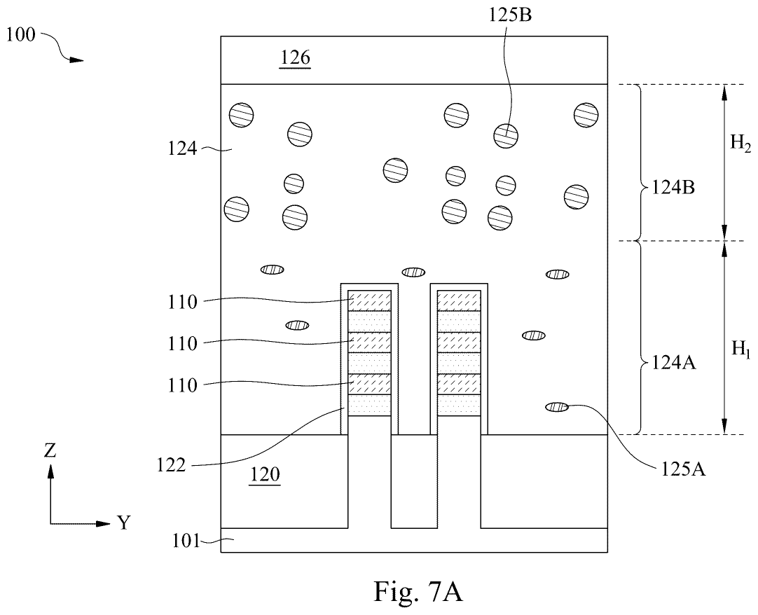

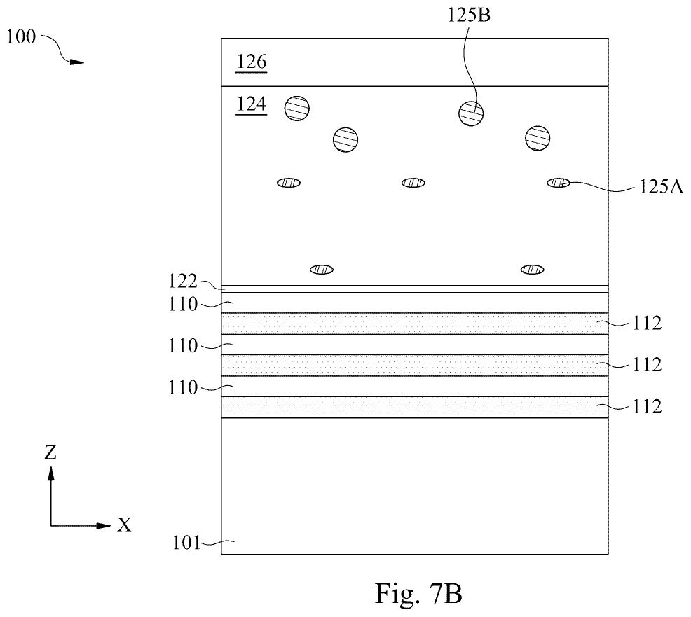

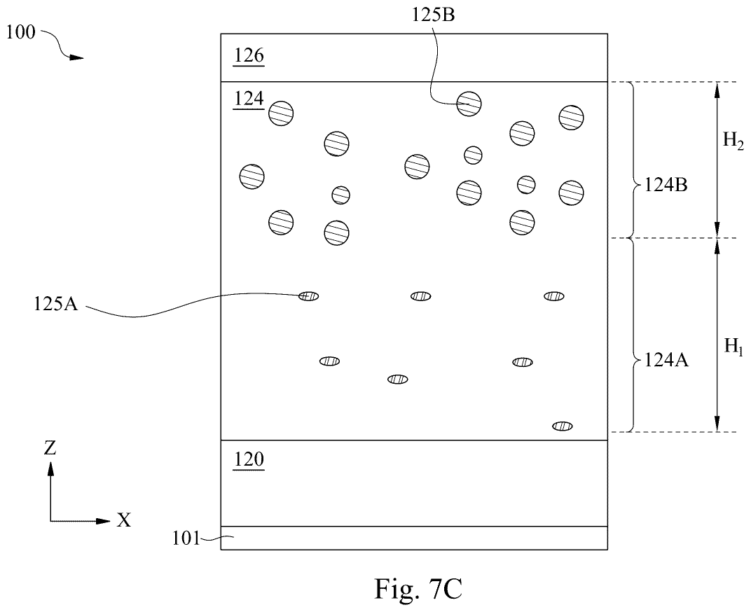

In FIGS. 7A-7C, dummy gate layer 124 is formed over the dielectric layer 122, in accordance with some embodiments. The dummy gate layer 124 may be an amorphous layer of Si, SiGe, Ge, a combination thereof, or the like. In some embodiments, the dummy gate layer 124 is formed by multi-staged deposition processes. For example, referring to FIG. 9, in the formation of the dummy gate layer 124, two-staged deposition processes are used. The two-staged deposition processes may include a first stage 210 and a second stage 220. In some embodiments, a planarization process such as CMP may be performed after the as-deposited dummy gate layer 124 is deposited. In some embodiments, the first stage 210 is used to form a lower portion 124A of the dummy gate layer 124, and the second stage 220 is used to form an upper portion 124B of the dummy gate layer 124. In some embodiments, an optional hard mask 126 is formed over dummy gate layer 124 before the etching process in the subsequent etch processes. The hard mask 132 may include one or more dielectric layers. For example, the hard mask 126 may be or include an oxide layer, a nitride layer, or a combination thereof. In an embodiment, the hard mask 126 includes silicon oxide, silicon nitride, silicon oxynitride, aluminum oxide, or a combination thereof.

In some embodiments, the first stage 210 includes at least one first cycle 212 and at least one second cycle 214. The first cycle 212 may include a deposition step 212a and an etch step 212b, and the second cycle 214 may include a deposition step 214a and has no etch step. The second stage 220 includes at least one third cycle 222 and at least one fourth cycle 224. Each third cycle 222 includes a deposition step 222a and an etch step 222b, and each the fourth cycle 224 includes a deposition step 224a and has no etch step.

In some embodiments, the deposition steps 222a, 224a in the first cycle 212 and the second cycle 214 is a low-pressure chemical vapor deposition (LPCVD), although other suitable processes may be applied. For example, the LPCVD process of the deposition steps 222a, 224a in the first cycle 212 and the second cycle 214 may be performed in a pressure of about 0.1 Torr to about 20 Torr, at a temperature of about 300 degrees Celsius to about 500 degrees Celsius (e.g., about 350 degrees Celsius to about 450 degrees Celsius), and with a time period of about 30 minutes to about 300 minutes. In an embodiment, precursors of the LPCVD processes in the first cycle 212 and the second cycle 214 include SiH₄, Si₂H₆, Si₃H₈, Si₄H₁₀, (CH₃)SiH₃, (CH₃)₂SiH₂, (CH₃CH₂)SiH₃, (CH₃)Si₂H₅, (CH₃)₂Si₂H₄, (CH₃)₆Si₂, tris(dimethylamino)silane (TDMAS), or combinations thereof. In some embodiments that the SiGe or Ge is included in the dummy gate layer 124, Ge-containing precursors are also used, for example, GeH₄ or the like.

In some embodiments, the etch step 212b in the first cycle 212 is a dry etch process, such as RIE or NBE. The etch process may be performed with a temperature of about 20 degrees Celsius to about 450 degrees Celsius with a time period of 30 seconds to about 1200 seconds. In some embodiments, the etch step includes an etchant CHF₃, CF₄, CHCl₃, Cl₂, HBr, or a combination thereof with a mixture with a N₂, He, or other suitable inert gas. In some embodiments, H₂ is also added as the etchant.

The first stage 210 includes performing the first cycle 212 multiple times (e.g., 5-7 times) and then performing second cycle 214 one or more times. Alternatively, the one or more second cycles 214 may be performed between any two of the first cycles 212. The etch step 212b in the first cycles 212 may trim the as-deposited dummy gate layer 124 and can adjust the profile of the lower portion 124A of the dummy gate layer 124, thereby providing the dummy gate layer 124 a better step coverage. Accordingly, with performing the first cycle 212 multiple times in forming the lower portion of the dummy gate layer 124, the lower portion 124A of the dummy gate layer 124 may fill in the trenches 116 between the semiconductor strips 108 with improved coverage on the STI regions 120 and the semiconductor strips 108. The repeated changes between the deposition steps and the etch steps with a relatively low deposition temperature (e.g., about 300 degrees Celsius to about 500 degrees Celsius in the deposition steps) in the first stage 210 may induce a few crystalline particles 125A to be formed in the lower portion 124A of the dummy gate layer 124 during the formation of the dummy gate layer 124. In some embodiments, the crystalline particles 125A have an elongate shape, an ellipsoid shape, an ellipsoid-like shape, a column shape, a column-like shape, or a combination thereof. In embodiments that the crystalline particles 125A exist, the crystalline particles 125A may have a length of less than about 4 nm and a width of less than about 4 nm.

In some embodiments, the deposition steps 222a, 224a in the third cycle 222 and the fourth cycle 224 is an LPCVD process, although other suitable processes may be applied. For example, the LPCVD processes of the deposition steps in the third cycle 222 and the fourth cycle 224 may be performed in a pressure of about 0.1 Torr to about 20 Torr, at a temperature of about 550 degrees Celsius to about 800 degrees Celsius (e.g., about 600 degrees Celsius to about 750 degrees Celsius), and with a time period of about 10 minutes to about 60 minutes seconds. In some embodiments, the precursors of the LPCVD process includes SiH₄, Si₂H₆, Si₃H₈, Si₄H₁₀, (CH₃)SiH₃, (CH₃)₂SiH₂, (CH₃CH₂)SiH₃, (CH₃)Si₂H₅, (CH₃)₂Si₂H₄, (CH₃)₆Si₂, tris(dimethylamino)silane (TDMAS), or combinations thereof. In some embodiments that the SiGe or Ge is included in the dummy gate layer 124, Ge-containing precursors are also used, for example, GeH₄ or the like. The precursors of the deposition steps used in the third cycle 222 and the fourth cycle 224 may be the same as the precursors of the deposition steps used in the third cycle 222 and the fourth cycle 224. In some embodiments, the deposition steps in the third cycle 222 and the fourth cycle 224 may be set to have same deposition parameters and with a greater temperature.

In some embodiments, the etch step in the third cycle 222 is a dry etch process, such as RIE or NBE. The etch process may be performed with a temperature of about 20 degrees Celsius to about 450 degrees Celsius and a time period of about 30 seconds to about 1200 seconds. In some embodiments, the etch step includes an etchant CHF₃, CF₄, CHCl₃, Cl₂, HBr, or a combination thereof with a mixture with a N₂, He, or other suitable inert gas. In some embodiments, H₂ may also be added as the etchant. In some embodiments, the etch step in the third cycle 222 is similar with the etch step in the first cycle 212. The second stage 220 includes performing the third cycle 222 multiple times (e.g., 3-5 times) and then performing the fourth cycle 224 one or more times. Alternatively, the one or more fourth cycles 224 may be performed between any two of the third cycles 222. The repeated changes between deposition steps and the etch steps with a relatively high deposition temperature (e.g., about 600 degrees Celsius to about 900 degrees Celsius in the deposition steps) may induce crystalline particles 125B to be formed in the upper portion 124B of the dummy gate layer 124 during the formation of the dummy gate layer 124. The number of crystalline particles 125B in the upper portion 124B of the dummy gate layer 124 may be greater than the number of the crystalline particles 125A in the lower portion 124A of the dummy gate layer 124. The crystalline particles 125B may have a sphere shape or a sphere-like shape. The crystalline particles 125B may have a radius of about 5 nm to about 200 nm. For example, the average size (e.g., volume) of the crystalline particles 125B is about 3 times greater than the average size (e.g., volume) of the crystalline particles 125A.

It was found that the crystalline particles 125A in the dummy gate layer 124 may generate a compressive stress, and the crystalline particles 125B in the dummy gate layer 124 may generate a tensile stress. Thus, the compressive stress and the tensile stress are compensated in the dummy gate layer 124. The residual stress of the dummy gate layer 124 may be reduced. Thus, the risks of bending the tall-thin semiconductor strips 108 because of the formation of dummy gate layer 124 may be reduced or avoided. In some embodiments, because the number and/or size of the crystalline particles 125B are greater than the crystalline particles 125A, the tensile stress may be greater than the compressive stress if the lower portion and the upper portion have the same height. Thus, increasing the height ratio between the heigh of the lower portion 124A and the height of the upper portion 124B of dummy gate electrode 130 may increase the compressive stress and decrease the tensile stress, thereby allowing the dummy gate layer 124 to generate less overall residual stress. For example, the lower portion 124A may have a height H₁ of about 20 nm to about 150 nm, and the upper portion 124B may have a height H₂ of about 10 nm to about 50 nm. In some embodiments, the height H₁ is the greater than the height from the top of the STI regions 120 to the top of the semiconductor strips 108. In some embodiments, the height H₁ is about 2 times the second height H₂ or greater. Except for the embodiments illustrated above, for various needs, it is appreciated that the height ratio H₁/H₂ can be adjusted in any suitable manner to adjust the compressive stress and the tensile stress.

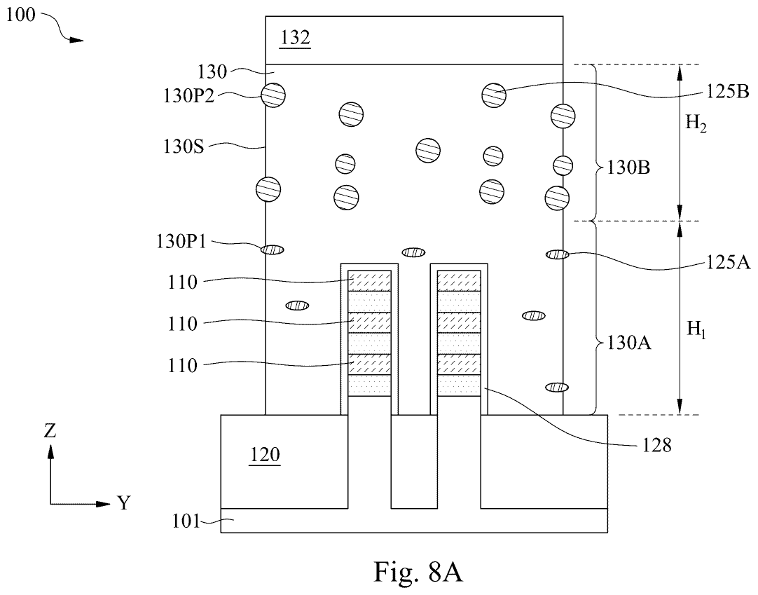

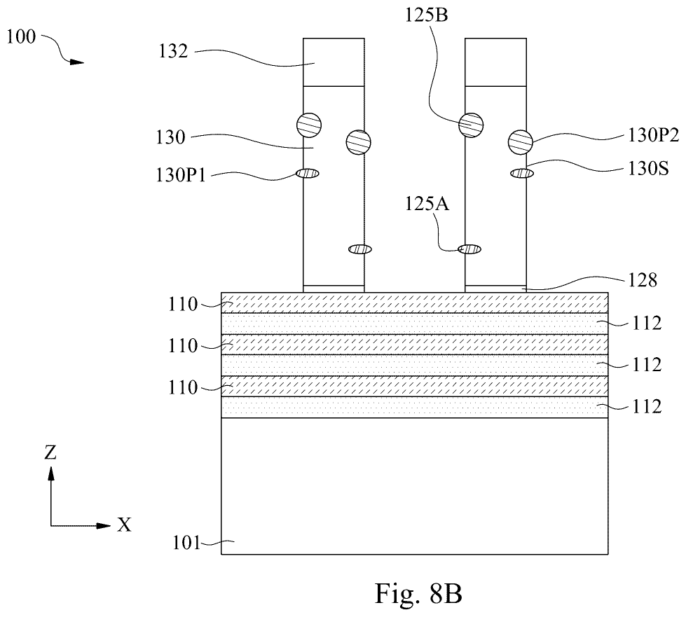

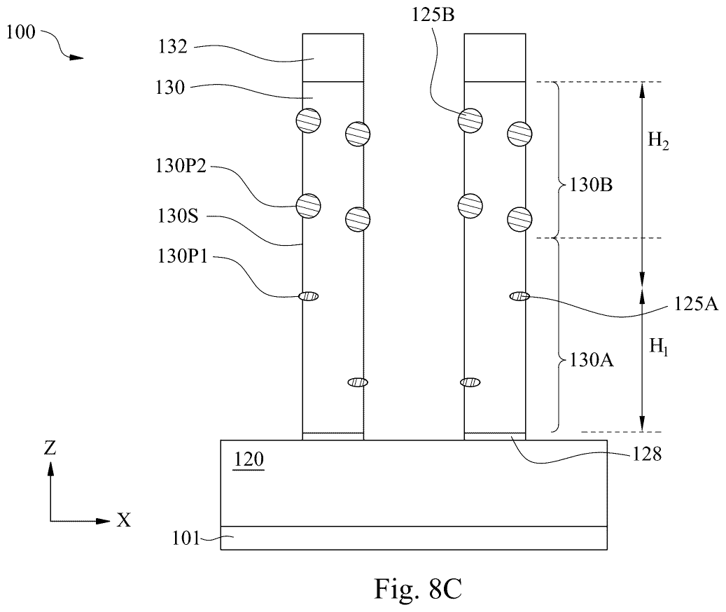

Referring to FIGS. 8A-8C, a patterning process 230 (see FIG. 9) is performed to from the dummy gate dielectrics 128 and the dummy gate electrodes 130, in accordance with some embodiments. For example, the dummy gate electrodes 130 and the dummy gate dielectrics 128 may be formed by patterning the dummy gate layer 124 and the dielectric layer 122 by one or more etch processes, in accordance with some embodiments. For example, a first etch process may be performed to etch the dummy gate layer 124 to form lines having a longitudinal axis along the X-direction, and a second etch process to cut to the lines to form the dummy gate electrodes 130. The dummy gate electrode 130 may have the longitudinal axis along the X-direction with a shorter length as compared to the lines formed by the first etch process. In some embodiments, the first etch process and the second etch process are an anisotropic etch process, such as RIE or NBE. When etching the dummy gate layer 124 to form the dummy gate electrodes 130, the hard mask 126 may be patterned to form patterned hard mask 132 first, and the first etch process and/or the second etch process transfer the pattern of the hard mask 132 to the dummy gate electrode 130. Referring to FIGS. 8A-8C, the hard mask 132 have flat sidewalls that define the locations of the major sidewall surfaces 130S of the dummy gate electrodes 130.

When etching the dummy gate layer 124, although anisotropic etch is used, the etch rate of etching the amorphous material of the dummy gate layer 124 is faster (e.g., at least 10 time) than the etch rate of etching the crystalline particles 125A and 125B. Thus, after the etching, the dummy gate electrode 130 may have protrusion formed of the crystalline particles protruding over the major sidewall surfaces 130S. The protrusions 130P2 protruding the sidewall major surface 130S may have a higher density (e.g., volume density and/or number density) in the upper portion 130B of the dummy gate electrode 130 than that of the protrusions 130P1 protruding over the sidewall major surface 130S in the lower portion 130A of the dummy gate electrode 130 in the X direction (e.g., FIG. 8C) and the Y-direction (e.g., FIG. 8A).

Due to lithography limits, the dummy gate electrodes 130 (measured from one major sidewall surface 130S to another major sidewall surface 130S) may be designed to have a predetermined pitch. Because the dummy gate electrodes 130 may be removed to form an openings for filling in the gate electrodes 170 (FIGS. 19A-C) in subsequent processes, the protrusions 130P1, 130P2 may enlarge the volume of the third openings 166 (FIGS. 19A-C), thereby allowing more material of the gate electrodes 170 to fill in. For example, few or no seam may be formed in the gate electrodes 170. With the device size continues to shrink, such space may increase the performance and/or reliability of the device, especially when the gate electrodes 170 include multiple layers (e.g., multiple work function layers) for providing different threshold voltages in various regions.

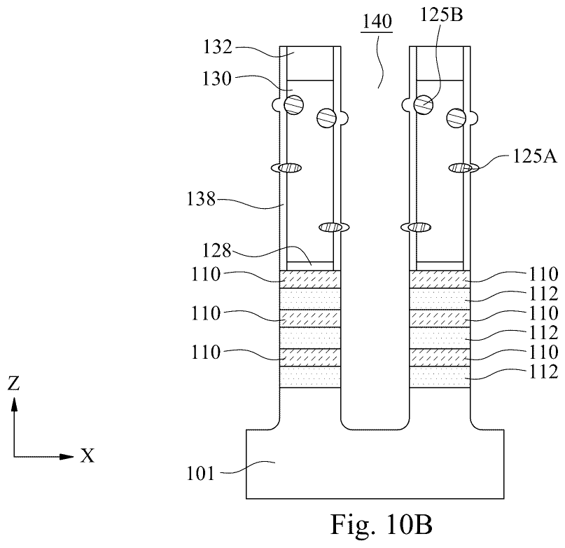

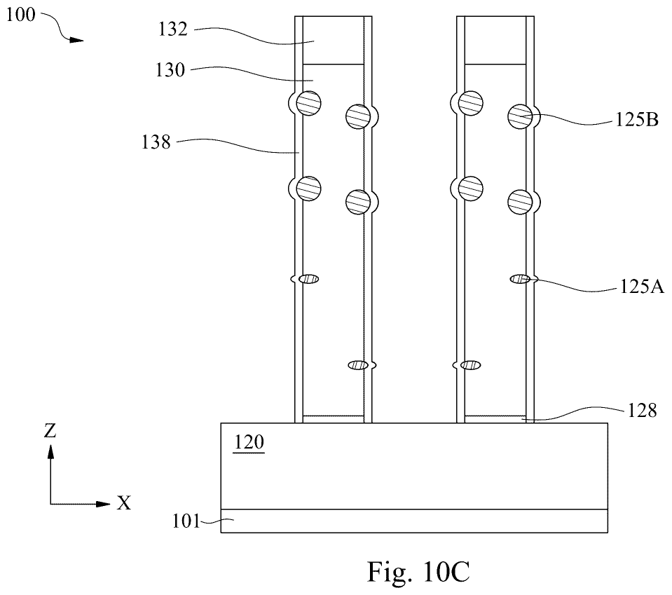

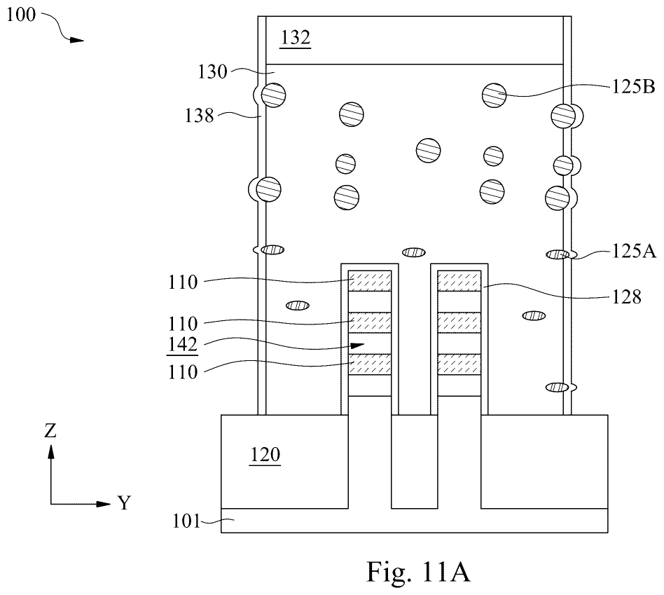

FIGS. 10A-20D continue to illustrate the cross-sectional views in manufacturing the semiconductor device 100, in accordance with some embodiments. In FIGS. 10A-10C, gate spacers 138 are formed on sidewalls of the dummy gate structures 134. The gate spacers 138 may include one or more layers. The gate spacers 138 may be formed by depositing a conformal layer and then anisotropically etching the conformal layer. The gate spacers 138 may independently be or include a dielectric material such as silicon oxide, silicon nitride, silicon carbide, silicon carbonitride, silicon oxycarbide, silicon oxycarbonitride, other suitable materials, or a combination thereof.

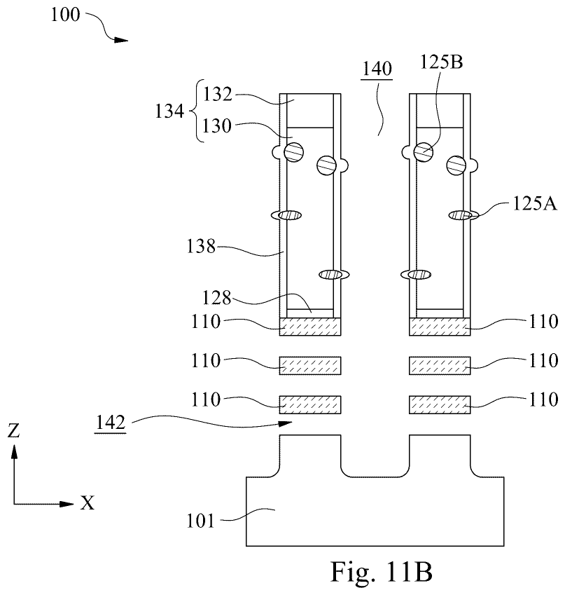

Next, proceeding to the intermediate structure illustrated in FIGS. 11A and 11B, first openings 140 are formed in the semiconductor strips 108, the fins 114, and the substrate 101, in accordance with some embodiments. The first openings 140 may be formed by removing at least portions of the semiconductor strips 108 and the substrate 101 that are not protected by the gate spacers 138 and the dummy gate structures 134. As such, the first openings 140 may be formed between neighboring dummy gate structures 134 in the X-direction as illustrated in FIG. 5. The first openings 140 may be recessed to below the top surfaces of the STI regions 120, although the first openings 140 can also be recessed to level with or above the top surfaces of the STI regions 120. The first openings 140 may be formed by an etch process, either isotropic or anisotropic etch process, and the etch process may be selective with respect to one or more crystalline planes of the substrate 101. The etch process may be a dry etch, such as a RIE, NBE, or the like, or a wet etch. The etchant from the etch process may include CH₂F₂, C₂F₆, CF₄, CHCl₃, SF₆, or the like or any suitable etchant.

As shown in FIGS. 11A and 11B, the second nanostructures 112 exposed by the first openings 140 are etched to form second openings 142, in accordance with some embodiments. That is, the second openings 142 may be space that was occupied by the second nanostructures 112, including the space between the vertically adjacent first nanostructures 110 and between the bottommost first nanostructure 110 and the substrate 101. In an embodiment that the second semiconductor material includes, e.g., SiGe, an etch process using a hydroxide etchant, such as tetramethylammonium hydroxide (TMAH), ammonium hydroxide (NH₄OH), or the like, is used.

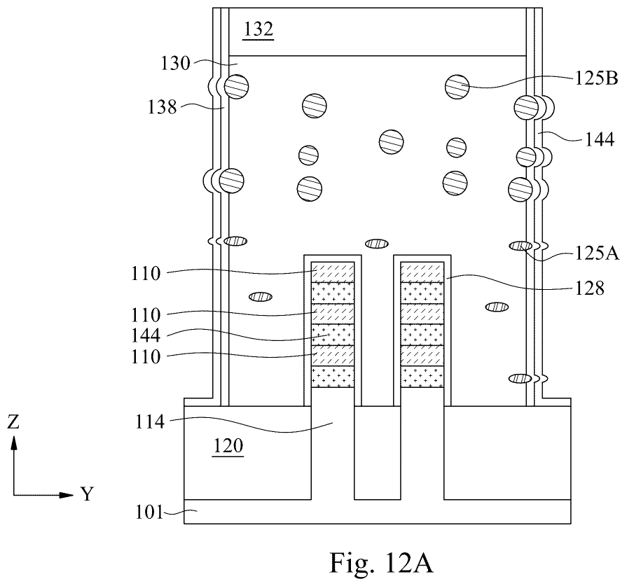

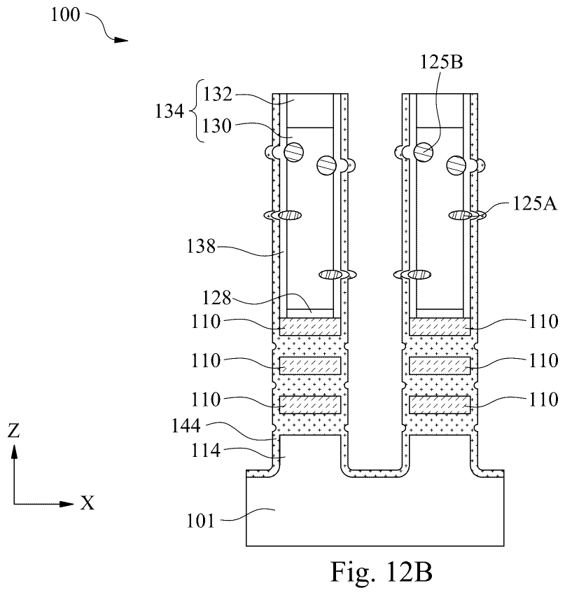

In FIGS. 12A and 12B, an insulating layer 144 is deposited in the first openings 140 and the second openings 142, in accordance with some embodiments. Given the size differences between the first openings 140 and the second openings 142, the insulating layer 144 may substantially or completely fill the second openings 142 and form a conformal layer in the first openings 140. The insulating layer 144 may include an oxide-containing material, such as silicon oxide, silicon oxynitride, fluorine-doped silicate glass (FSG), a low-K dielectric material, or any suitable dielectric material. In some embodiments, the insulating layer 144 includes a material similar to those of the STI regions 120. The insulating layer 144 may be formed by any suitable depositing method, such as FCVD, ALD, PECVD, LPCVD, combinations thereof, or the like.

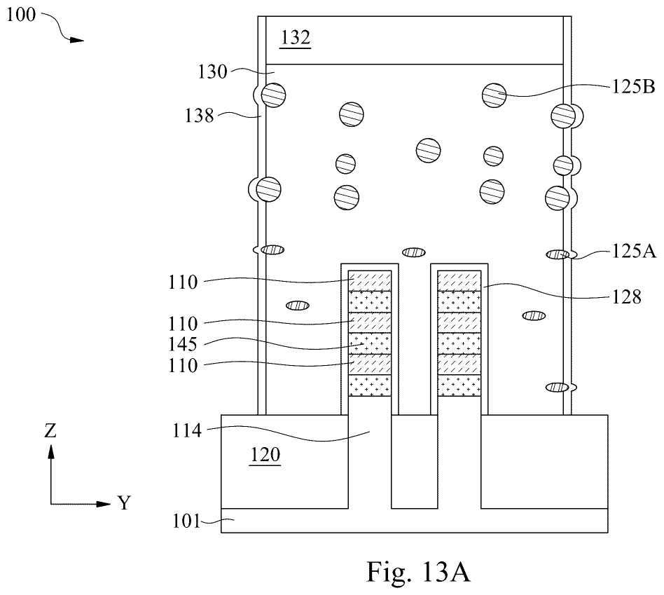

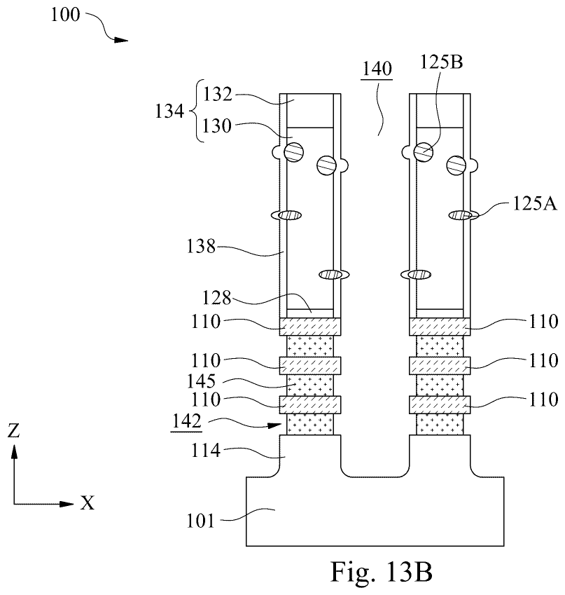

In FIGS. 13A and 13B, an etch process is performed to remove the insulating layer 144 in the first openings 140 and partially recess the insulating layer 144 in the second openings 142, thereby forming insulating nanostructures 145 in the second openings 142, in accordance with some embodiments. The etch process may use etchants selective to etch the insulating layer 144, and the first nanostructures 110 and the substrate 101 may remain relatively unetched. The etch process may be an isotropic etch process. In some embodiments, the isotropic etch process is performed for a sufficient time to remove the insulating layer 144 in the first openings 140 and laterally recess the insulating layer 144 in the second openings 142. Accordingly, the insulating layer 144 is substantially or completely removed in the first openings 140. In an embodiment in which the insulating layer 144 remains in the first openings 140 after the isotropic etch process, a further anisotropic process may be performed to substantially or completely remove the insulating layer 144 in the first openings 140. For example, the isotropic etch process include an etchant including hydrofluoric acid, the like, a mixture therefore, or other suitable etchants.

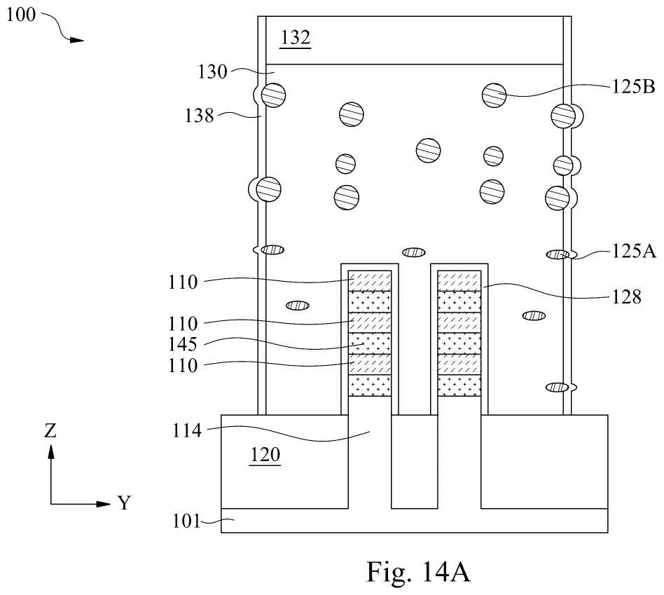

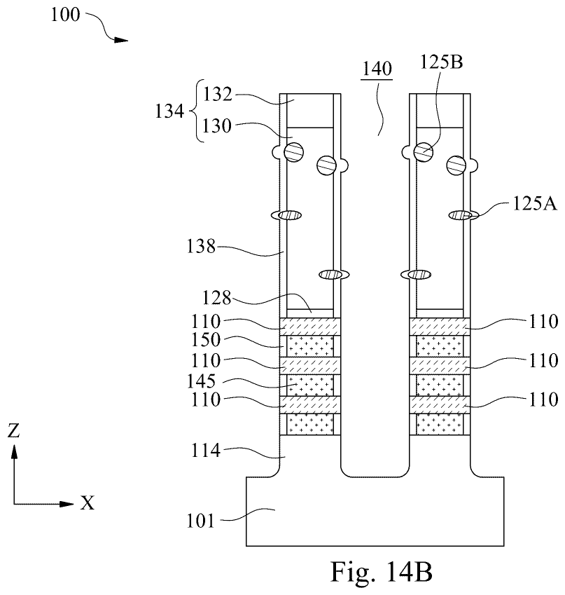

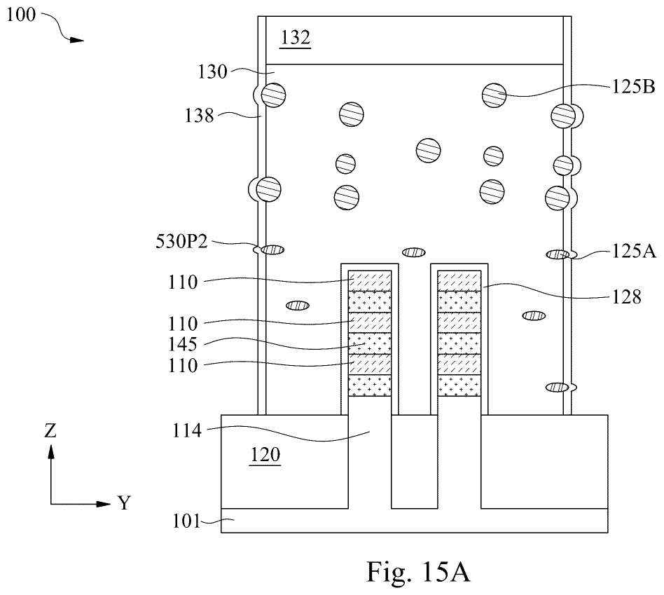

In FIGS. 14A and 14B, inner spacers 150 are formed in the lateral recesses and on the sidewalls of the insulating nanostructures 145, in accordance with some embodiments. The inner spacers 150 may act as isolation features between subsequently formed epitaxial structures and a gate structure. As will be discussed in greater detail below, epitaxial structures will be formed in the first openings 140, and the insulating nanostructures 145 will be replaced with gate structures. Thus, the structural profiles of the gate structures may be determined by the structural profiles of the insulating nanostructures 145.

In some embodiments, an inner spacer layer is deposited by a conformal deposition process, such as CVD, ALD, or the like. The inner spacer layer may include a material such as silicon nitride, silicon oxynitride or silicon carbonitride, although any suitable material, such as a low-K dielectric material such as SiOC or SiOCN, may be utilized. The inner spacer layer may then be anisotropically etched to form the inner spacers 150, such as by RIE, NBE, or the like, using the gate spacers 138 as a mask. Although outer sidewalls of the inner spacers 150 are illustrated as being flush with sidewalls of the first nanostructures 110 in FIG. 14B, the outer sidewalls of the inner spacers 150 may extend beyond or be recessed from sidewalls of the first nanostructures 110. Moreover, although the outer sidewalls of the inner spacers 150 are illustrated as being straight in FIG. 14B, the outer sidewalls of the inner spacers 150 may be concave or convex. The inner spacers 150 may have a thickness of about 3 nm to about 8 nm.

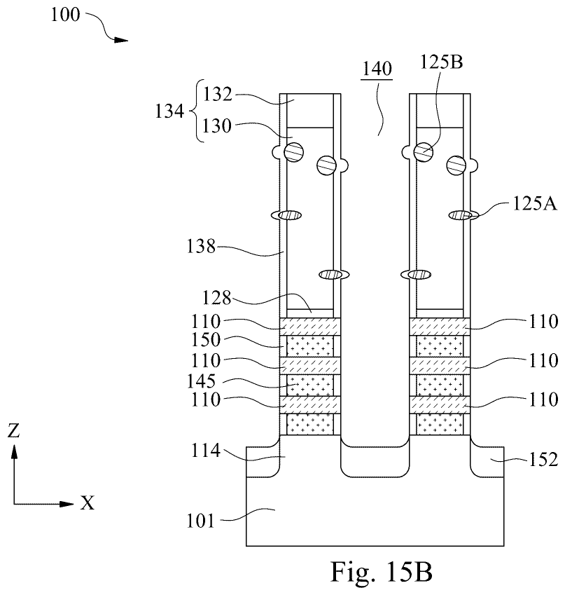

In FIGS. 15A and 15B, a buffer layer 152 is formed on the exposed substrate 101 the first openings 140 in the PMOS region 100A and the NMOS region 100B, in accordance with some embodiments. In an embodiment, the buffer layer 152 is or includes an undoped silicon or undoped SiGe, and the buffer layer 152 may be formed by a selective epitaxial process, thereby selectively forming on semiconductor surfaces, such as on the exposed surfaces of the substrate 101 and the sidewall surfaces of the first nanostructures 110. In some embodiments, the buffer layer 152 includes a dielectric material for reducing current leakage from source/drain regions. In such embodiments, the buffer layer 152 is formed by any suitable deposition processes.

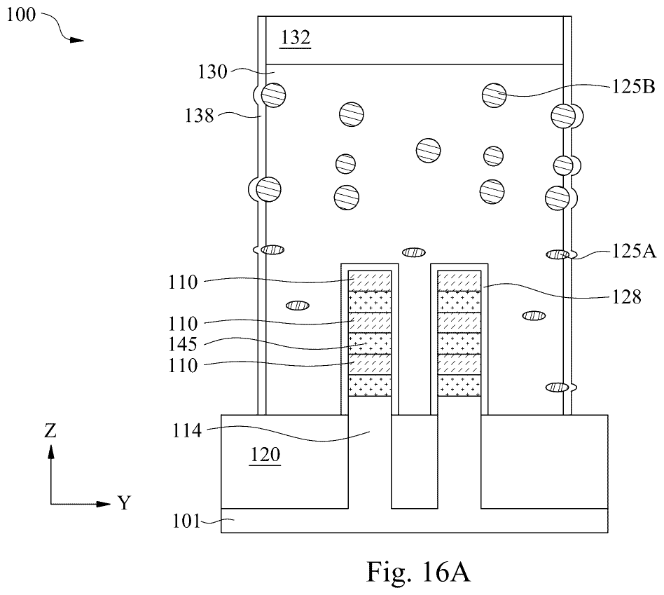

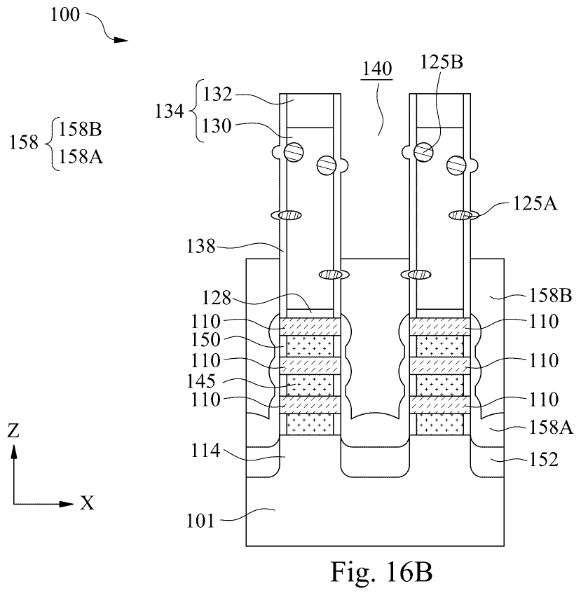

In FIGS. 16A and 16B, source/drain regions 158 are formed in the first openings 140 and over the dielectric filling 154, in accordance with some embodiments. In this disclosure, a source region and a drain region are interchangeably used, and the structures thereof are substantially the same. Furthermore, source/drain region(s) may refer to a source or a drain, individually or collectively, depending upon the context. The source/drain regions may exert stress on the first nanostructures 110, thereby improving device performance. The source/drain regions 158 may be made of one or more layers of Si, SiP, SiC and SiCP for n-channel FETs or one or more layers of Si, SiGe, Ge for p-channel FETs. For p-type field effect transistors (PFETs), p-type impurities, such as boron, boron fluoride, indium, or the like, may be included in the source/drain regions 158. For n-type field effect transistors (NFETs), n-type impurities, such as phosphorus, arsenic, antimony, or the like, may be included in the source/drain regions 158. The source/drain regions 158 may be formed by an epitaxial growth method using such as, CVD, ALD, MBE, combinations therefore, or the like, and can also be referred to as epitaxial source/drain features 158. In some embodiments, the impurities may be in situ doped when epitaxially depositing the source/drain regions 158. The source/drain region 158 may have an impurity concentration of between about 1×10¹⁹ atoms/cm³ and about 1×10²¹ atoms/cm³. In some embodiments, the source/drain regions 158 grow to form facets, which may correspond to crystalline planes of the material used for the substrate 101. In some embodiments, each source/drain region 158 includes one or more layers, such as including a first layer 158A and a second layer 158B are illustrated in the FIG. 16B. In an embodiment, the first layer 158A and the second layer 158B comprises a same semiconductor material (e.g., SiGe or SiC) with different concentrations. For example, the second layer 158B may have a greater Ge concentration or C concentration than that of the first layer 158A. In some embodiment, the second layer 158B has a greater impurity concentration (e.g., B or P) than that of the first layer 158A.

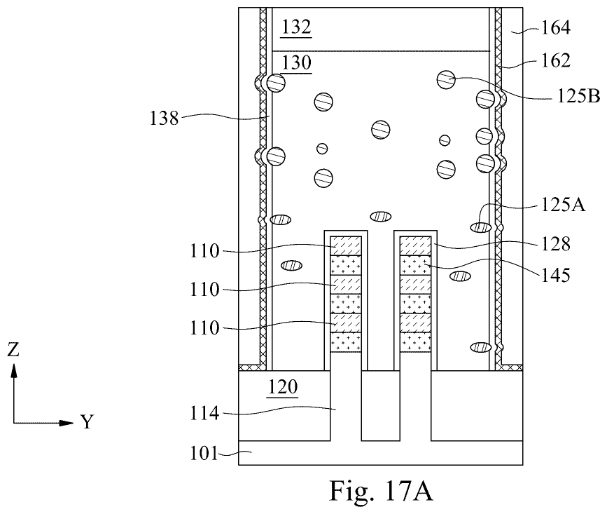

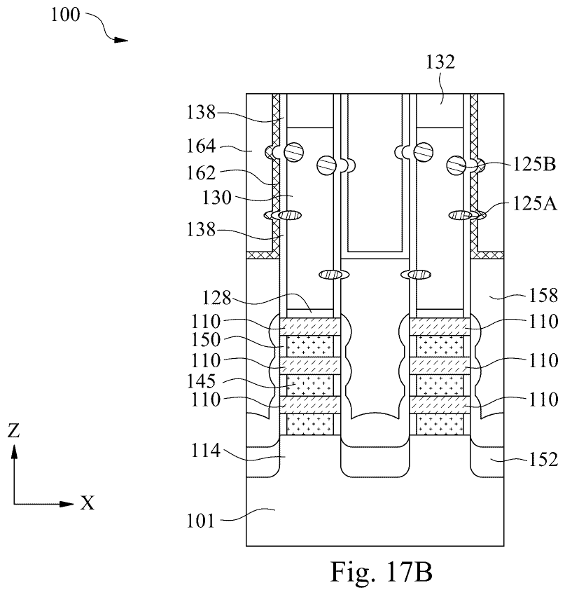

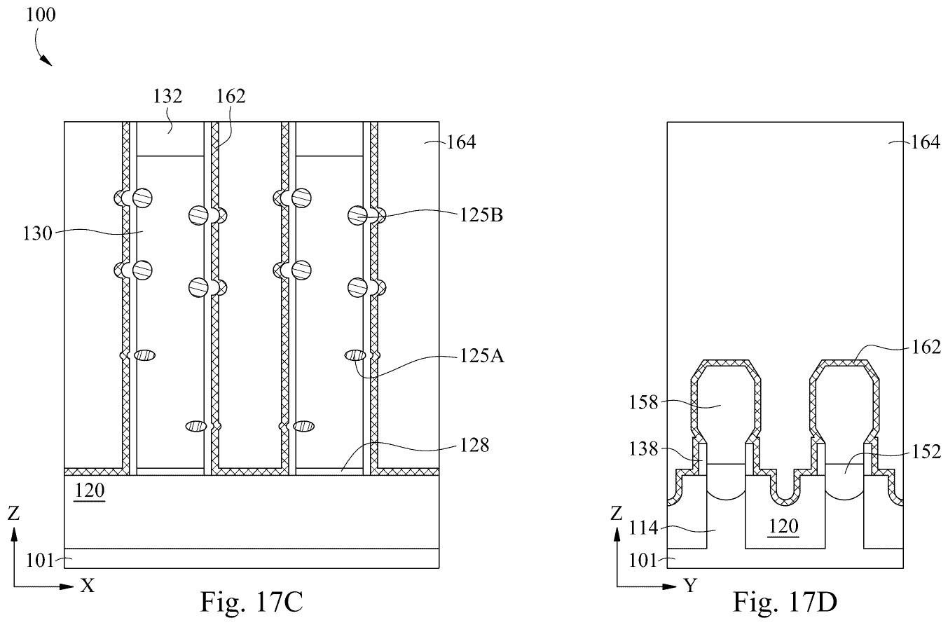

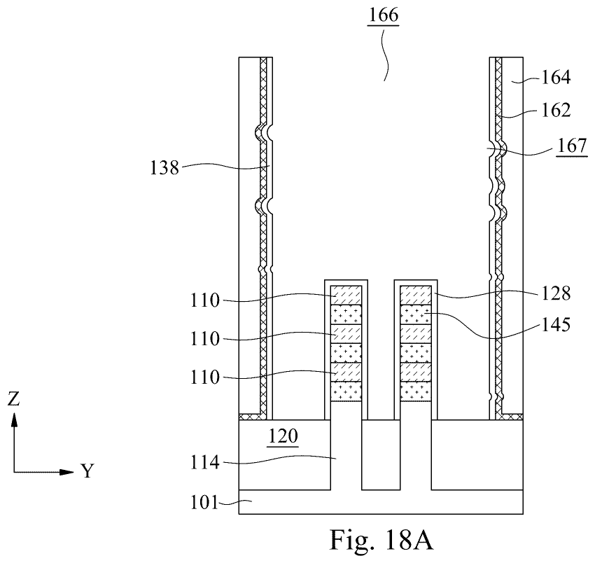

In FIGS. 17A-17D, a contact etch stop layer (CESL) 162 is conformally formed on the exposed surfaces of the semiconductor device 100, in accordance with some embodiments. The CESL 162 covers the STI regions 120, the source/drain regions 158, and the sidewalls of the gate spacers 138. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device 100. The materials for the first ILD layer 164 may include compounds including Si, O, C, and/or H, such as silicon oxide, SiCOH, SiOC, PSG, BSG, BPSG, combinations thereof, or the like. Organic materials, such as polymers, may also be used for the first ILD layer 164. The first ILD layer 164 may be deposited by FCVD, PECVD, or other suitable deposition techniques. In some embodiments, after the first ILD layer 164 is deposited, a thermal process is performed to cure the first ILD layer 164. After the first ILD layer 164 is formed, a planarization operation, such as CMP, is performed to level the top surface of the first ILD layer 164 with the top surfaces of dummy gate electrodes 130 or the hard masks 132. In some embodiments in which the hard masks 132 remain, the planarization process levels the top surface of the first ILD layer 164 with the top surfaces of the hard masks 132 and the gate spacers 138. In some embodiments, top surfaces of the dummy gate electrodes 130, the gate spacers 138, and the first ILD layer 164 are level within process variations after the planarization process. In such embodiments, the top surfaces of the dummy gate electrodes 130 are exposed through the first ILD layer 164.

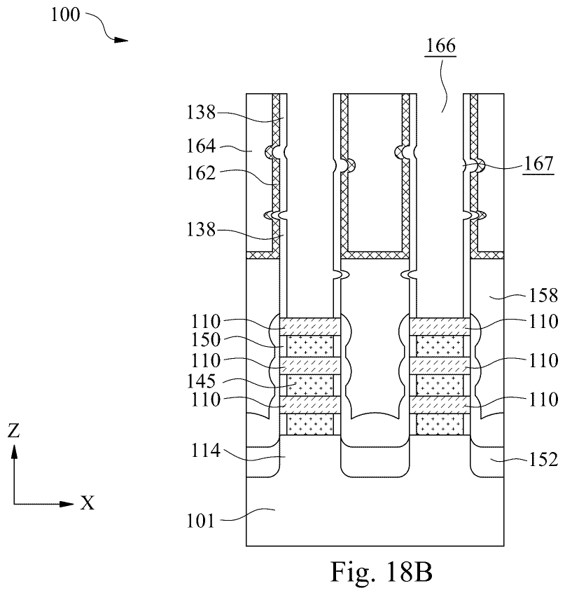

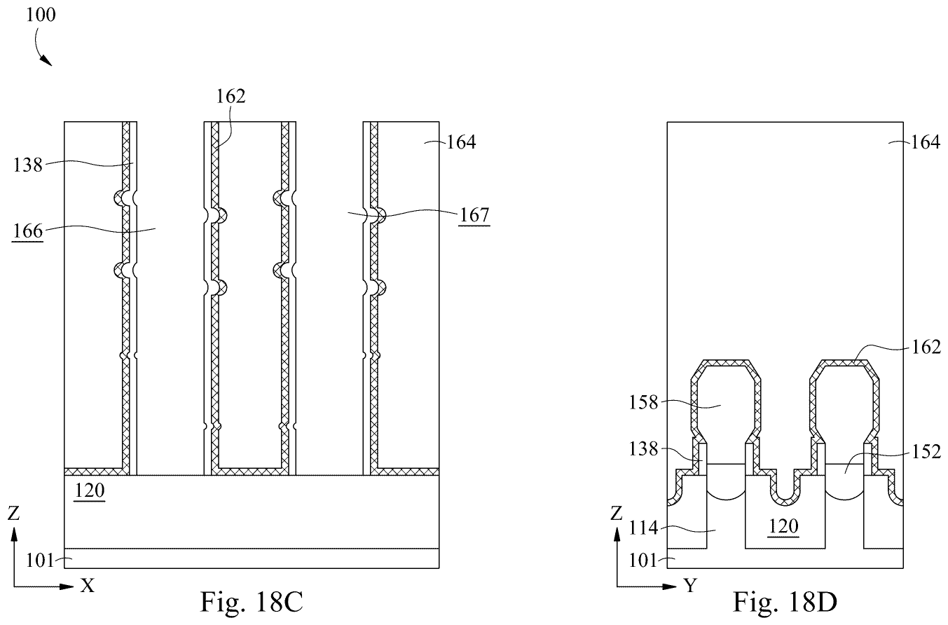

In FIGS. 18A-18D, the dummy gate electrodes 130, the hard masks 132 (if exist), and the insulating layer 144 are removed. In some embodiments, the dummy gate dielectrics 128 are also removed after the dummy gate electrodes 130 are removed. The hard masks 132, the dummy gate electrodes 130 and the dummy gate dielectrics 128 may be removed by one or more etch processes. For example, an etch process may be performed by etching the hard masks 132 using the dummy gate electrodes 130 as an etch stop, etching the dummy gate electrodes 130 using the dummy gate dielectrics 128 as an etch stop, and the dummy gate dielectrics 128 are then removed by another etch process. In some embodiments, the etch process for etching the dummy gate electrodes 130 and the dummy gate dielectrics 128 may include using reaction gas(es) that selectively etch the dummy gate electrodes 130 and the dummy gate dielectrics 128 at a faster rate than the first ILD layer 164 or the gate spacers 138.

After the dummy gate dielectrics 128 and the dummy gate electrodes 130 are removed, the insulating nanostructures 145 are exposed, and an isotropic etch process may be performed to remove the insulating nanostructures 145. The isotropic etch process may include a wet etching containing an etchant containing a dilute HF or other suitable etchants. The removal of the hard masks 132, the dummy gate electrodes 130, the dummy gate dielectrics 128, and the insulating nanostructures 145 forms third openings 166. In some embodiments, the third openings 166 include caves 167 that were occupied by the protrusions 130P1, 130P2.

Next, in FIGS. 19A-19D, gate dielectric layers 168 and gate electrodes 170 are formed for replacement gates, in accordance with some embodiments. The gate dielectric layers 168 are deposited conformally in the third openings 166. The gate dielectric layers 168 may be formed on top surfaces and sidewalls of the substrate 101 and on exposed surfaces of the first nanostructures 110, In some embodiments, the gate dielectric layers 168 are also deposited on top surfaces of the first ILD layer 164, the CESL 162, the gate spacers 138, and the STI regions 120. In some embodiments, the gate dielectric layers 168 include one or more layers of a dielectric material, such as silicon oxide, silicon nitride, or high-K dielectric material, other suitable dielectric material, and/or combinations thereof. Examples of high-K dielectric material include HfO, HfSiO, HfSiON, HfTaO, HfTiO, HfZrO, zirconium oxide, aluminum oxide, titanium oxide, hafnium oxide-alumina (HfO—AlO) alloy, other suitable high-K dielectric materials, and/or combinations thereof. The gate dielectric layers 168 may be formed by CVD, ALD, or any suitable deposition techniques.

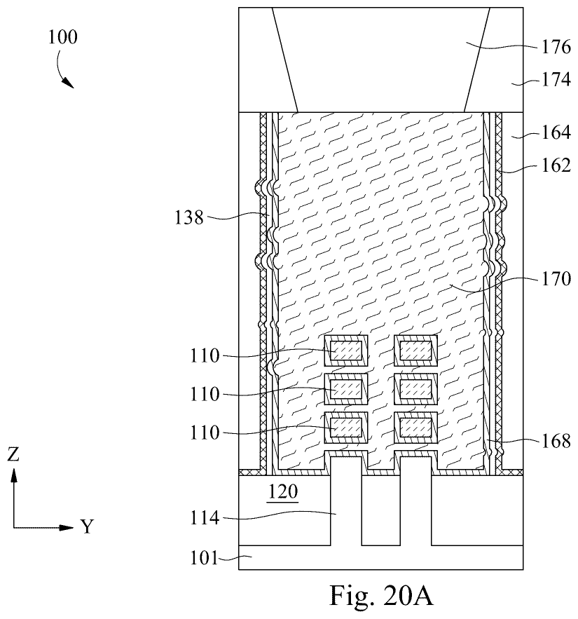

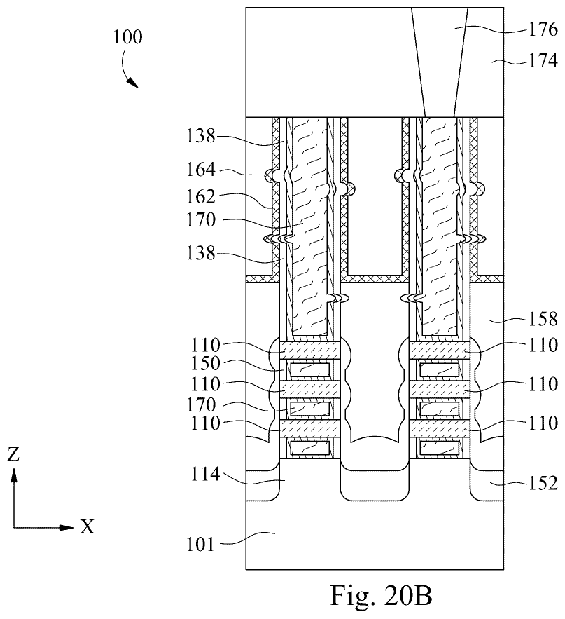

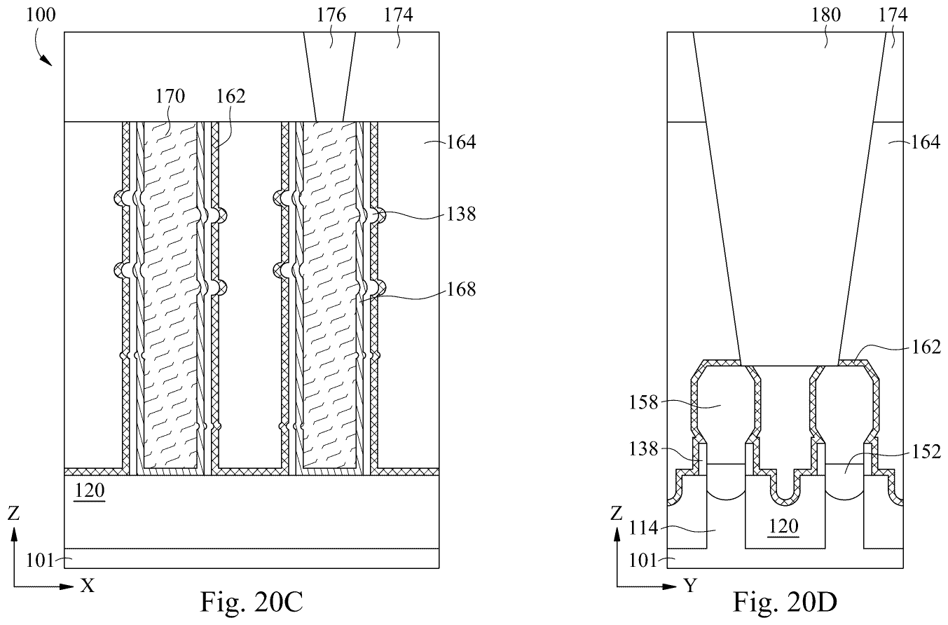

The gate electrodes 170 are deposited over the gate dielectric layer 168, respectively, and fill the remaining portions of the third openings 166. The gate electrodes 170 may include a metal-containing material such as a titanium-based material (e.g., titanium nitride or titanium oxide), tantalum nitride, tantalum carbide, cobalt, ruthenium, aluminum, tungsten, combinations thereof, or multi-layers thereof. Although single-layer gate electrodes 170 are illustrated in FIGS. 20A and 20B, the gate electrodes 170 may comprise any number of liner layers, any number of work function tuning layers, and a fill material. Because the extra volume created by caves 167, the gate electrodes 170 may have less or no seam when filling the third openings 166. The gate electrodes 170 may be formed by CVD, ALD, electro-plating, or other suitable deposition techniques. After filling the third openings 166, excess materials of the gate dielectric layers 168 and the gate electrodes 170 over the top surface of the first ILD layer 164 are then removed by a planarization process, such as CMP, until the top surfaces of the first ILD layer 164 are exposed. The remaining portions of the gate electrodes 170 and the gate dielectric layers 168 thus form replacement gate structures of the semiconductor device 100. The gate electrodes 170 and the gate dielectric layers 168 may be collectively referred to as gate structures 172. The gate structures 172 may surround channels (e.g., the first nanostructures 110) of the semiconductor device 100. In some embodiments, the gate electrode 170 may have a lower portion 170A and an upper portion 170B. The lower portion 170A may have a height H₃ substantially similar to the height H₁ of the lower portion 130A of the dummy gate electrode 130. The upper portion 170B may have a height H₄ substantially similar to the height H₂ of the upper portion 130B of the dummy gate electrode 130, although the height H₄ may be at least about 20% less than the second height H₂ depending on the height of the hard mask 132 and/or the thickness removed by the CMP. In some embodiments, the height H₄ is about a half or less than the second height H₂. Protrusions 170P1 in the lower portion 170A of the gate electrode 170 may protrude over the major side surface 170S, and protrusions 170P2 in the upper portion 170B of the gate electrode 170 may protrude over the major side surface 170S. The protrusions 170P1 may have a higher density (e.g., volume density and/or number density) in the upper portion 170B of the gate electrode 170 than that of the protrusions 170P2 protruding over the sidewall major surface 170S in the lower portion 130A of the gate electrode 170, in the X direction (e.g., FIG. 19C) and the Y-direction (e.g., FIG. 19A).

Next, in FIGS. 20A-20D, a second ILD 174 is deposited over the first ILD layer 164 and over the gate structures 172 and the first ILD layer 164. In some embodiments, the second ILD 174 is a film formed by FCVD. In some embodiments, the second ILD 174 is formed of a dielectric material such as PSG, BSG, BPSG, USG, or a low-k material, or the like, and may be deposited by any suitable method, such as CVD, PECVD, or the like. In some embodiments, the second ILD 174 has a height thinner than the total height of the gate electrode 170 (e.g., H₃+H₄) in the Z-direction.

Contacts 176 and 180 (may also be referred to as contact plugs) are formed in the second ILD 174. The contacts 176 and 180 may each comprise one or more layers, such as barrier layers, diffusion layers, and fill materials. For example, in some embodiments, the contacts 176 includes a barrier layer and a low-resistance conductive material over the barrier layer. The contact 176 is electrically coupled to the underlying conductive feature such as gate structure 172 and can be referred to as a gate contact. The contacts 180 includes an optional silicide layer, the barrier layer over the silicide layer, and the low-resistance conductive material over the barrier layer. The contact 180 may be electrically coupled to the underlying conductive feature such as source/drain regions 158 and may be referred to as a source/drain contact. The barrier layer may include titanium, titanium nitride, tantalum, tantalum nitride, or the like. The low-resistance conductive material may be copper, a copper alloy, silver, gold, tungsten, cobalt, aluminum, nickel, or the like. The low-resistance conductive material may occupy a major volume of the contact 176 or 180, and therefore the contact 176 or 180 may have an electrical conductivity than the electrical conductivity of the source/drain regions 158. A planarization process, such as a CMP, may be performed to remove excess material of contacts 176 and 180 from a surface of the second ILD 174.

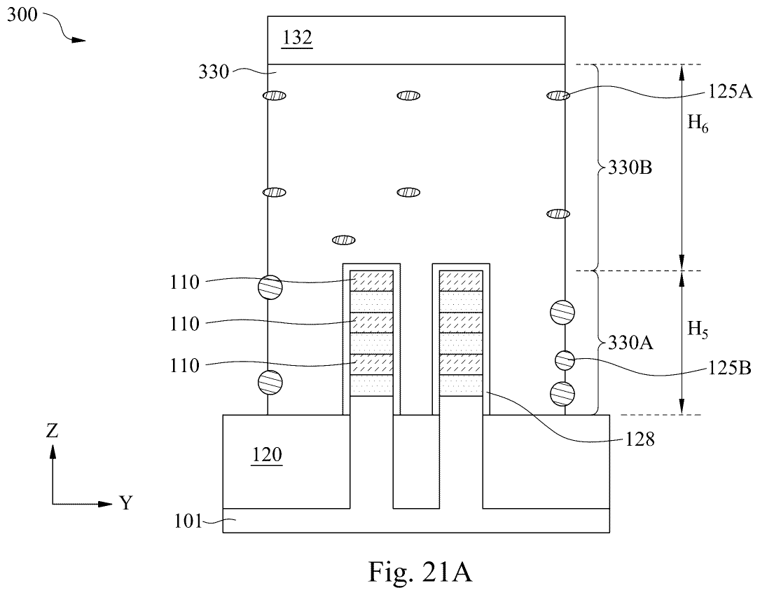

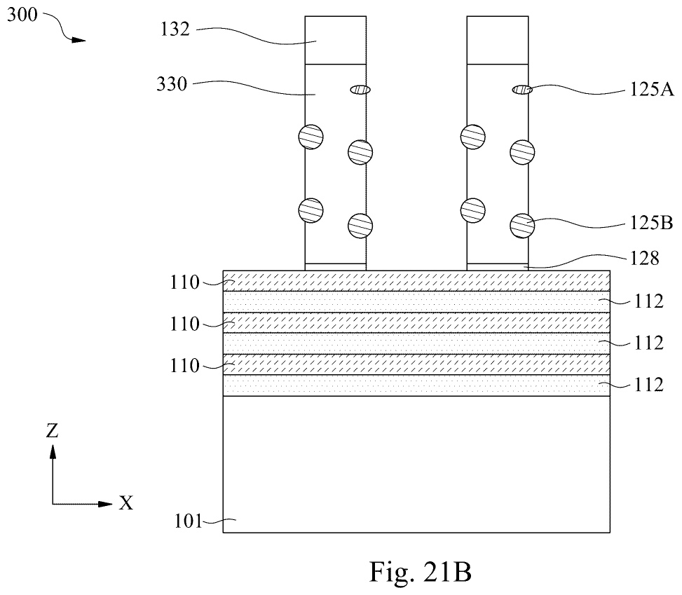

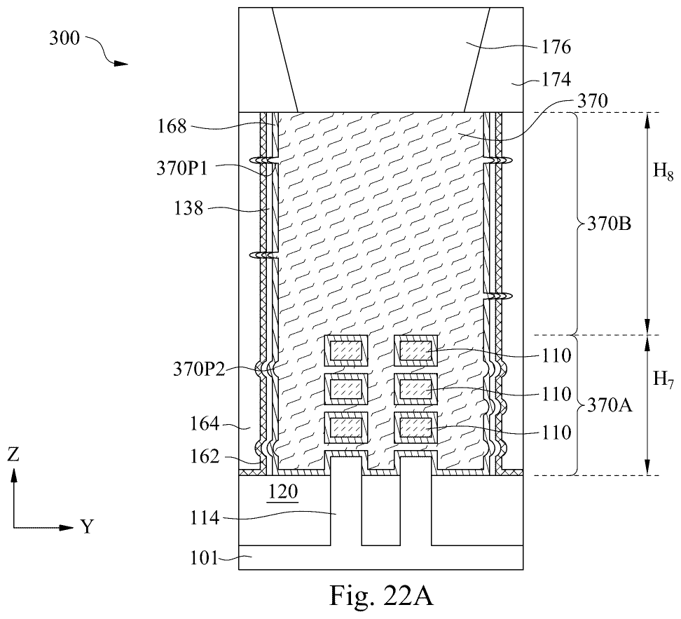

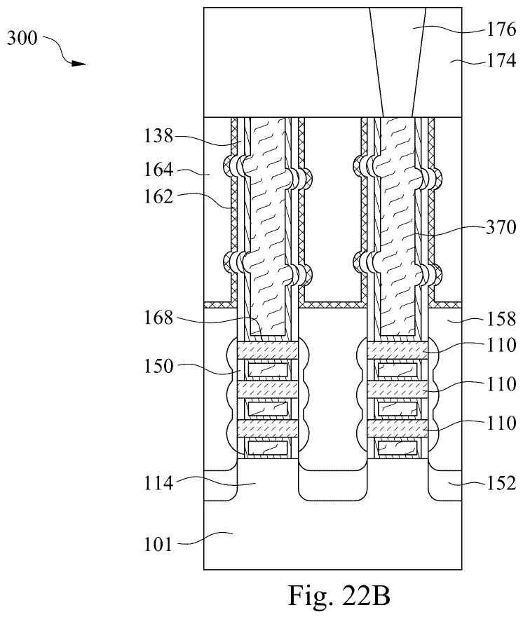

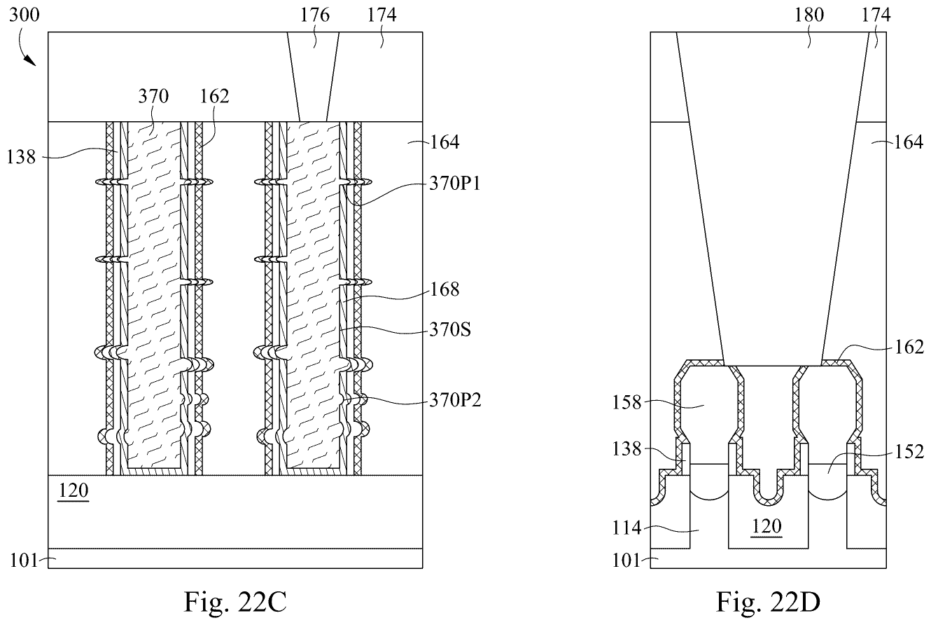

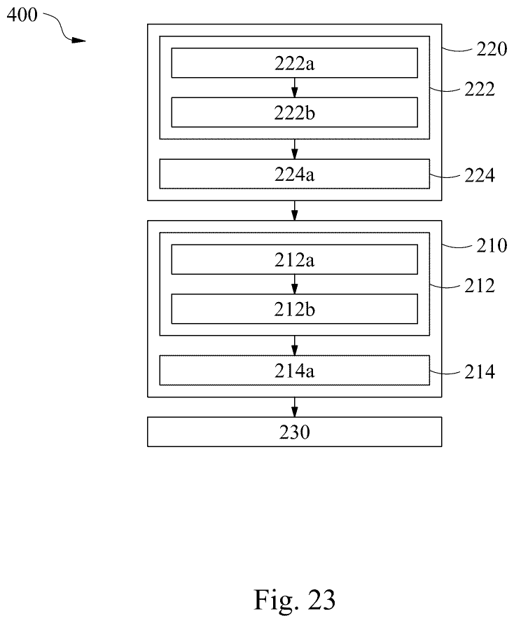

FIGS. 21A-22C illustrate a cross-sectional view of intermediate stages in manufacturing a semiconductor device 300, in accordance with some embodiments. The semiconductor device 300 is similar to the semiconductor device 100, wherein same reference numeral represents same elements. The dummy gate electrode 330 of the semiconductor device 300 may be formed by the flow 400 illustrated in FIG. 23. The flow 400 is similar to the flow 200 except that the sequence of the first stage 210 and the second stage 220 are reversed. Accordingly, referring to FIG. 21A, crystalline particles 125B are formed in a lower portion 330A of the dummy gate electrode 330, and crystalline particles 125A are formed in an upper portion 330B of the dummy gate electrode 330. In some embodiments, to compensate the compress stress and the tensile stress, the height H₅ of the lower portion 330A of the dummy gate electrode 330 may be smaller than the height H₆ of the upper portion 330B of the dummy gate electrode 330. For example, the height H₆ may be two times the height H₅ or greater. The height H₅ may be smaller than the height of the semiconductor strip protruding over the top surface of the STI region 120.

Next, processes similar to FIGS. 10A-20D may proceed, and a resulting exemplary structure of semiconductor device 300 is illustrated in FIGS. 22A-22D, in accordance with some embodiments. The gate electrodes 370 are formed to replace the dummy gate electrodes 330. The gate electrodes 370 may be or include similar material to the gate electrodes 170 and may be formed by methods similar to those of forming the gate electrodes 170. In some embodiments, the gate electrode 370 may have a lower portion 370A and an upper portion 370B. The lower portion 370A may have a height H₇ substantially similar to the height H₅ of the dummy gate electrode 330. The upper portion 370B may have a height H₈ substantially similar to the height H₆ of the dummy gate electrode 330 although the height H₈ may be at least about 20% less than the height H₆ depending on the height of the hard mask 132 and/or the thickness removed by the CMP. Protrusions 370P2 in the lower portion 370A of the gate electrode 370 may protrude over the major side surface 370S, and protrusions 370P1 in the upper portion 370B of the gate electrode 370 may protrude over the major side surface 370S. The protrusions 370P1 may have a lower density (e.g., volume density and/or number density) in the upper portion 370B of the gate electrode 370 than that of the protrusions 370P2 protruding over the sidewall major surface 370S in the lower portion 370A of the gate electrode 370, in the X direction (e.g., FIG. 22C) and the Y-direction (e.g., FIG. 22A).

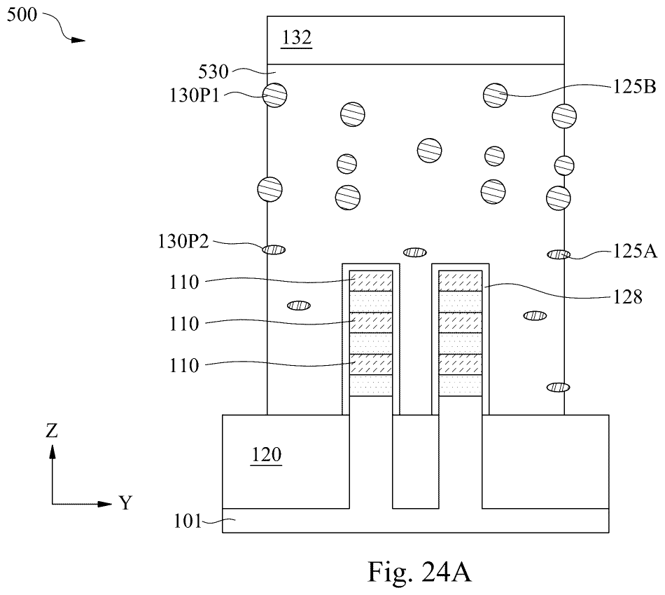

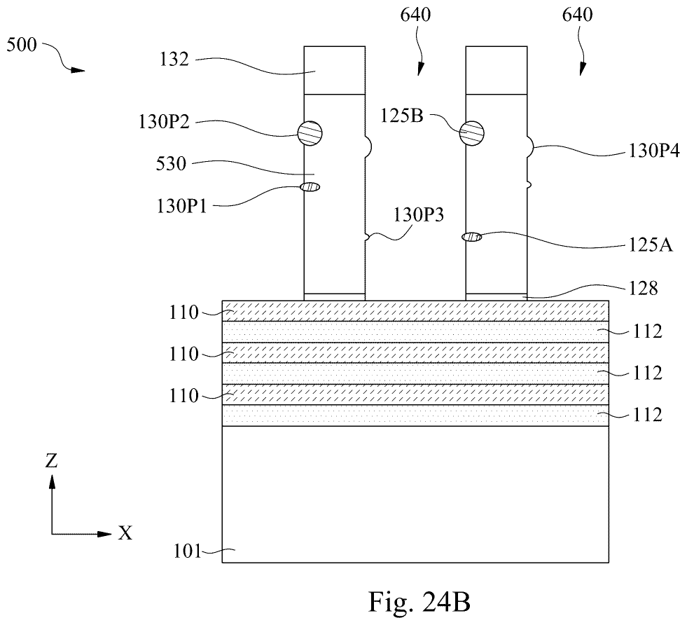

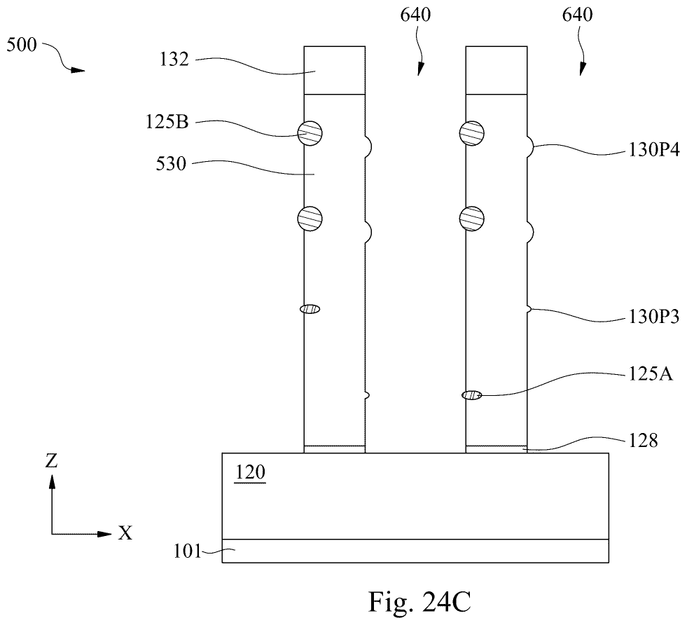

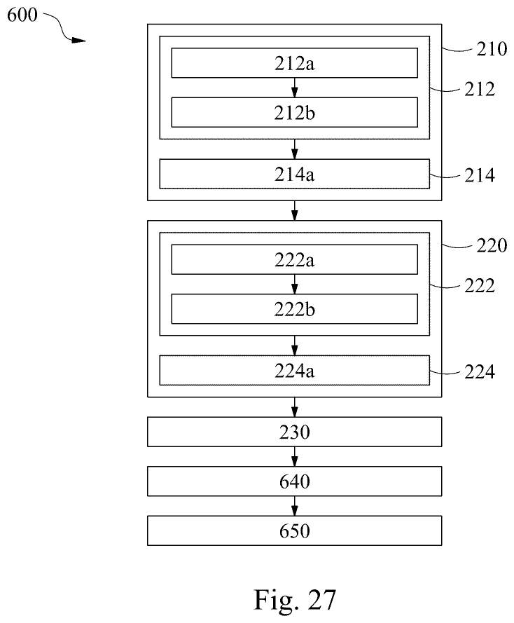

FIGS. 24A-26D illustrate a cross-sectional view of intermediate stages in manufacturing a semiconductor device 500, in accordance with some embodiments. The semiconductor device 500 is similar to the semiconductor device 100, wherein same reference numeral represents same elements. In the semiconductor device 500, protrusion on one side of the dummy gate electrode may be converted from crystalline phase to amorphous phase by an implantation process and can be removed in a further etch process. FIG. 27 illustrates a flow 600 of in manufacturing the dummy gate electrodes 530 of the semiconductor device 500, in accordance with some embodiments. The flow 600 is similar to the flow 200 with adding an ion bombardment process 640 and an additional patterning process 650.

The processes for forming the dummy gate electrode 530 are similar to those of forming the dummy gate electrodes 130. For example, formation of the semiconductor device 500 may include similar processes may proceeding from FIG. 1 to FIG. 9C. Thereafter, referring to FIGS. 24A-24C, an ion bombardment process 640 is implemented for bombarding the crystalline particles 125A, 125B protruding over one sidewall major surface 130S of the dummy gate electrode 130 (FIG. 9A-9C), in accordance with some embodiments. For example, referring to FIGS. 24B and 24C, the ion bombardment process may be performed in the X-direction. The crystalline particles 125A, 125B being bombarded may convert to amorphous, and the protrusions 130P1, 130P2 being bombarded may convert to amorphous protrusions 130P3, 130P4. The ion bombardment process may use heavy atoms such as As, Sb, Sn, Ga, In, or a combination thereof. The ion bombardment process may be performed with a tilt angle of about 1 degree to about 45 degrees with respect to the Z-direction. In some embodiments, the ion bombardment process includes an ion energy of about 5 KeV to about 50 KeV and a dose of 1×10¹⁴ atoms/cm² to about 3×10¹⁵ atoms/cm².

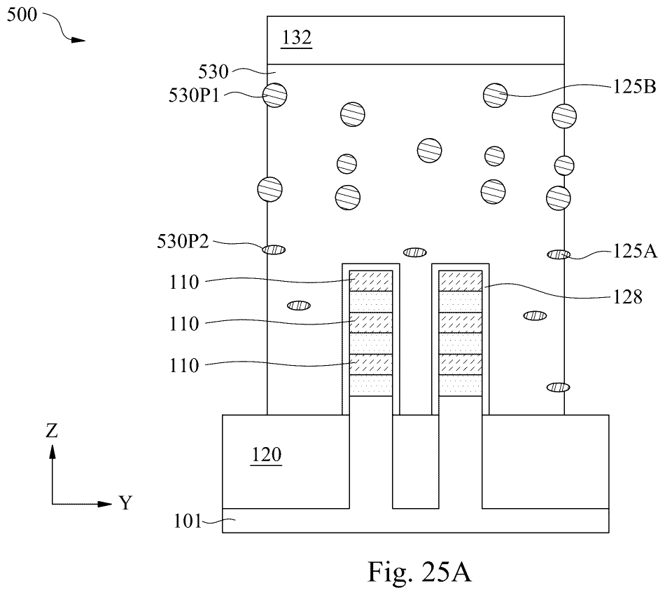

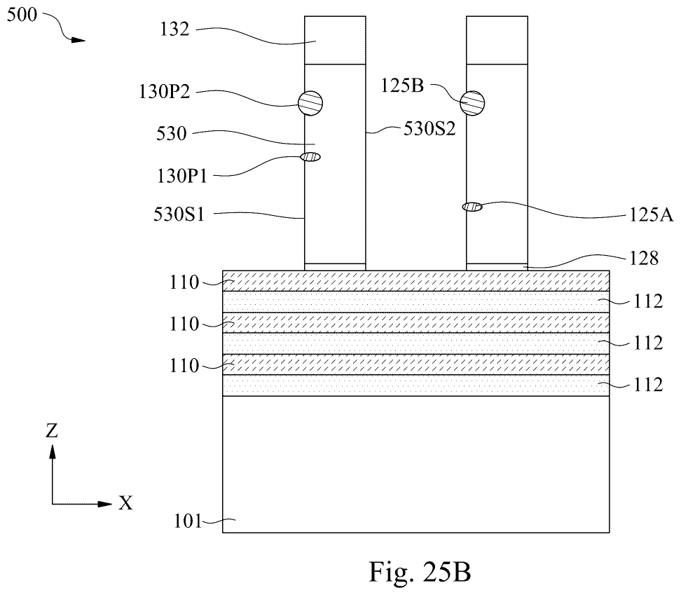

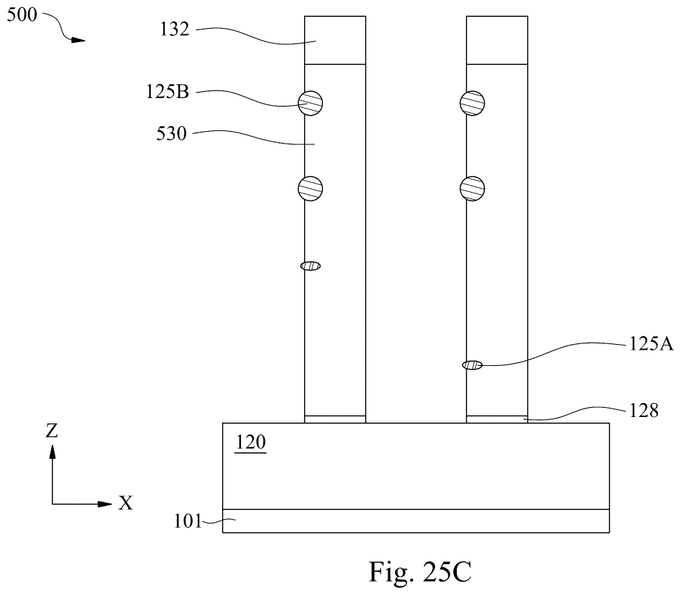

Next, referring to FIGS. 25A-25C, an etch process is performed to etch the dummy gate electrode 130 using the hard mask 132 as the mask, thereby forming the dummy gate electrodes 530 in accordance with some embodiments. The etch process may be an anisotropic process. The etch process may remove the amorphous protrusions 130P3 and 130P4 from one sides of the dummy gate electrodes 530 in the X-direction. Thus, one respective dummy gate electrode 530 may have protrusions 130P1 and 130P2 protruding over one sidewall major surface 530S1, and an opposite sidewall surface 530S2 opposite the sidewall major surface 530S1 is a flat surface in the X-direction.

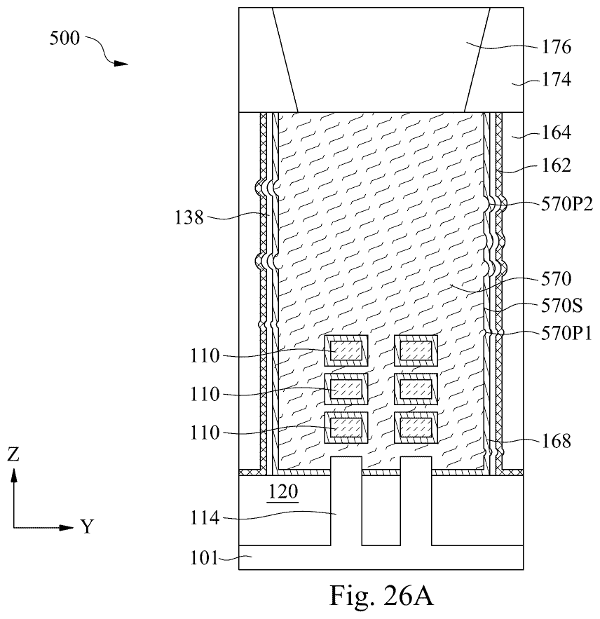

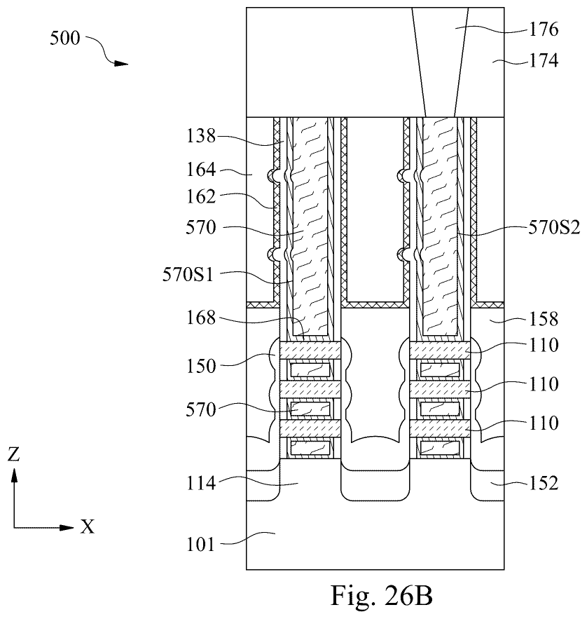

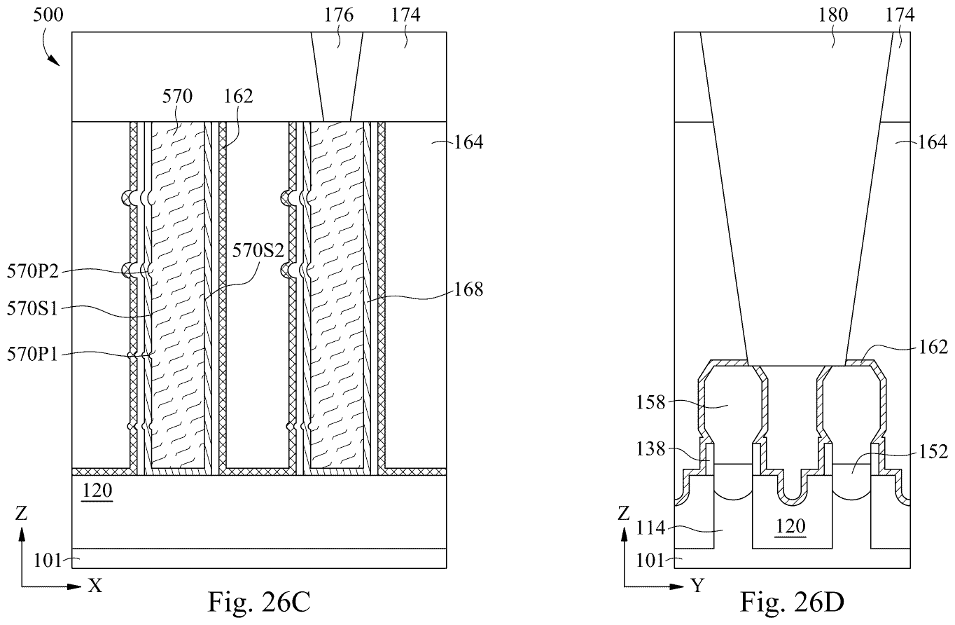

Next, processes similar to FIGS. 10A-20D may proceed, and a resulting exemplary structure of semiconductor device 500 is illustrated in FIGS. 26A-26D, in accordance with some embodiments. The gate electrode 570 in the semiconductor device 500 only have one-sided protrusions in the cross-sectional view along the X-direction. The gate electrode 570 may be similar to the gate electrode 170 with having one flat surface 570S2 in the X-direction. For example, the gate electrode 570 may have protrusions 570P1 and protrusions 570P2 protruding over one major sidewall surface 570S1, and the opposite sidewall surface 570S2 in the X-direction is a flat surface.

Although embodiments illustrated above only shows an exemplary structure that the gate electrode 570 having one flat surface, it is appreciated more implantation process may be performed to covert more sidewall surfaces to the flat surface. Depending on the design requirement, the processes 640 and 650 may be only implemented on specific regions of the wafer. For example, a mask layer (e.g., photoresist) may be applied to other regions when preforming the processes 640 and 650 on the substrate. Thus, an integrated device may have the semiconductor device 100 and/or 300 formed in a first region and the semiconductor device 500 in a second region, in accordance with some embodiments.

Embodiments of the present disclosure provide a semiconductor device and methods for manufacturing it. The method includes forming a dummy gate layer over semiconductor strips. The dummy gate layer has different crystalline particles in its lower portion and upper portion. Accordingly, the dummy gate layer may generate less stress to the semiconductor strips underlying the dummy gate layer, which may reduce the risks that the semiconductor strips being bent and damaged resulting from the formation of the dummy gate layer. In addition, the crystalline particles may generate protrusions on the sidewalls, which may create more space for fill in replacement gate electrodes when the gate electrodes have a given pitch.

An embodiment is a semiconductor device. The semiconductor device includes a substrate; a channel region disposed over the substrate; a gate dielectric layer disposed over the channel region; a gate electrode disposed over the channel region and having a longitudinal axis extending in a first direction, wherein the gate electrode includes a lower portion and an upper portion over the lower portion, wherein the gate electrode includes a first sidewall extending along the first direction and including a first major surface, first protrusions protruding over the first major surface in the lower portion of the gate electrode, and second protrusions protruding over the first major surface in the upper portion of the gate electrode, wherein the first major surface is a flat surface, wherein a density of the first protrusions in the lower portion of the gate electrode is less than a density of the second protrusions in the upper portion of the gate electrode, wherein the gate electrode includes a Ti-based material; a gate spacer disposed over the first protrusions, the second protrusions, and first major surface of the first sidewall of the gate electrode, wherein the gate spacer includes a bottom surface lower than the top surface of the channel region; and epitaxial source/drain features interposing the channel region in a second direction perpendicular to the first direction. In an embodiment, the lower portion of the gate electrode has a first height in a vertical direction, and the upper portion of the gate electrode has a second height in the vertical direction, wherein the first height is greater than the second height. In an embodiment, the channel region includes a plurality of nanostructures vertically stacked, wherein the lower portion of the gate electrode and the upper portion of the gate electrode connects at level that is higher than a top surface of the uppermost one of the nanostructures. In an embodiment, the first protrusions have a first average size in a vertical direction, and the second protrusions have a second average size in the vertical direction, wherein the second average size is greater than the first average size. In an embodiment, the gate dielectric layer wraps around the channel region and is further conformally disposed over the first major surface, the first protrusions, and the second protrusions. In an embodiment, the gate spacer includes a second sidewall, wherein the second sidewall includes a second major surface and third protrusions protruding over the second major surface, wherein the second major surface is aligned with a side surface of the channel region interfacing one of the epitaxial source/drain features. In an embodiment, the gate electrode includes a third sidewall opposite the first sidewall, wherein the third sidewall is a flat surface. In an embodiment, the gate electrode includes a fourth sidewall extending in the second direction, wherein the fourth sidewall includes a third major surface, fourth protrusions protruding over the third major surface in the lower portion of the gate electrode, and fifth protrusions protruding over the third major surface in the upper portion of the gate electrode, wherein a density of the fourth protrusions in the lower portion of the gate electrode is less than a density of the fifth protrusions in the upper portion of the gate electrode.

Another embodiment is a semiconductor device. The semiconductor device includes a substrate; a channel region disposed over the substrate; a gate electrode having a longitudinal axis in a first direction and over the nanostructures, wherein the gate electrode includes a first sidewall extending along the first direction and a second sidewall extending along a second direction perpendicular to the first direction, wherein the first sidewall includes a first major surface and first protrusions protruding over the first major surface, and the second sidewall includes a second major surface and second protrusions protruding over the second major surface, wherein the first major surface and the second major surface are flat surfaces; epitaxial source/drain features interposing the channel region in the second direction; an insulating layer disposed over the epitaxial source/drain features; and a contact extending through the insulating layer to be electrically coupled to the epitaxial source/drain features, wherein an electrical conductivity of the contact is greater than an electrical conductivity of the epitaxial source/drain features. In an embodiment, the semiconductor device further includes a third sidewall opposite the second sidewall, wherein the third sidewall includes a third major surface and third protrusions protruding over the third major surface. In an embodiment, the first protrusions and the third protrusions are not symmetrical to each other. In an embodiment, the semiconductor device further includes a fourth sidewall opposite the first sidewall, wherein the fourth sidewall is a flat surface. In an embodiment, the semiconductor device further includes a gate dielectric layer conformally disposed over the first major surface and the first protrusions of the first sidewall and the second major surface and the second protrusions of the second sidewall. In an embodiment, the channel region includes a plurality of nanostructures stacked vertically, wherein a gate spacer conformally disposed over the gate dielectric layer, wherein the gate spacer includes a fifth sidewall that includes a fourth major surface and fourth protrusions protruding over the fourth major surface, wherein the fourth major surface is aligned with a side surface of one of the nanostructures interfacing one of the epitaxial source/drain features.

A further embodiment is a method of forming a semiconductor device. The method includes: forming a semiconductor strip over a substrate, wherein the semiconductor strip includes first semiconductor layers and second semiconductor layers stacked alternatingly; forming a dummy gate layer over the substrate and crossing over the semiconductor strip, wherein the forming the dummy gate layer includes: performing a first cycle multiple times and a second cycle at least one time, wherein the first cycle includes a first deposition step and a first etch step, and the second cycle includes a second deposition step and has no etch step, wherein the first deposition step and the second deposition step is operated at a first temperature; and performing a third cycle multiple times and a fourth cycle at least one time, wherein the third cycle includes a third deposition step and a second etch step, and the second cycle includes a fourth deposition step and has no etch step, wherein the third deposition step and the fourth deposition step is operated at a second temperature greater than the first temperature; forming gate spacers over sidewalls of the dummy gate layer; etching the first semiconductor layer and the second semiconductor layer along the gate spacers to form first nanostructures and second nanostructures, respectively; forming epitaxial source/drain features interposing the first nanostructures, wherein each of the epitaxial source/drain features includes two layers that contain a same semiconductor material with different concentrations; replacing the second nanostructures and the dummy gate layer with a gate electrode; and forming an interlayer dielectric layer over the gate electrode and the epitaxial source/drain features, wherein the interlayer dielectric layer has a height thinner than a total height of the gate electrode. In an embodiment, wherein the first deposition step, the second deposition step, the third deposition step, and the fourth deposition step are low-pressure chemical vapor deposition. In an embodiment, wherein the first deposition step, the second deposition step, the third deposition step, and the fourth deposition step are operated in a pressure of about 0.1 torr to about 20 torr, wherein the first temperature is about 350 to about 500 degrees Celsius, and the second temperature is about 550 to about 800 degrees. In an embodiment, the replacing the second nanostructures and the dummy gate layer with the gate electrode includes: replacing the second nanostructures with insulating nanostructures; and replacing the insulating nanostructures and the dummy gate layer with the gate electrode. In an embodiment, the first cycle is performed 5-7 times, and the second cycle is performed 3-5 times. In an embodiment, the dummy gate layer has substantially no residual stress.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a channel region disposed over the substrate;
a gate dielectric layer disposed over the channel region;
a gate electrode disposed over the channel region and having a longitudinal axis extending in a first direction, wherein the gate electrode comprises a lower portion and an upper portion over the lower portion, wherein the gate electrode comprises a first sidewall extending along the first direction and comprising a first major surface, first protrusions protruding over the first major surface in the lower portion of the gate electrode, and second protrusions protruding over the first major surface in the upper portion of the gate electrode, wherein the first major surface is a flat surface, wherein a density of the first protrusions in the lower portion of the gate electrode is less than a density of the second protrusions in the upper portion of the gate electrode, wherein the gate electrode comprises a titanium based material;
a gate spacer disposed over the first protrusions, the second protrusions, and first major surface of the first sidewall of the gate electrode, wherein the gate spacer comprises a bottom surface lower than a top surface of the channel region; and
epitaxial source/drain features interposing the channel region in a second direction perpendicular to the first direction.

2. The semiconductor device of claim 1, wherein the lower portion of the gate electrode has a first height in a vertical direction, and the upper portion of the gate electrode has a second height in the vertical direction, wherein the first height is greater than the second height.

3. The semiconductor device of claim 2, wherein the channel region comprises a plurality of nanostructures vertically stacked, wherein the lower portion of the gate electrode and the upper portion of the gate electrode connects at level that is higher than a top surface of the uppermost one of the nanostructures.

4. The semiconductor device of claim 1, wherein the first protrusions have a first average size in a vertical direction, and the second protrusions have a second average size in the vertical direction, wherein the second average size is greater than the first average size.

5. The semiconductor device of claim 1, wherein the gate dielectric layer wraps around the channel region and is further conformally disposed over the first major surface, the first protrusions, and the second protrusions.

6. The semiconductor device of claim 1, wherein the gate spacer comprises a second sidewall, wherein the second sidewall comprises a second major surface and third protrusions protruding over the second major surface, wherein the second major surface is aligned with a side surface of the channel region interfacing one of the epitaxial source/drain features.

7. The semiconductor device of claim 1, wherein the gate electrode comprises a third sidewall opposite the first sidewall, wherein the third sidewall is a flat surface.

8. The semiconductor device of claim 1, wherein the gate electrode comprises a fourth sidewall extending in the second direction, wherein the fourth sidewall comprises a third major surface, fourth protrusions protruding over the third major surface in the lower portion of the gate electrode, and fifth protrusions protruding over the third major surface in the upper portion of the gate electrode, wherein a density of the fourth protrusions in the lower portion of the gate electrode is less than a density of the fifth protrusions in the upper portion of the gate electrode.

9. A semiconductor device, comprising:
a substrate;
a channel region disposed over the substrate;
a gate electrode having a longitudinal axis in a first direction and over the channel region, wherein the gate electrode comprises a first sidewall extending along the first direction and a second sidewall extending along a second direction perpendicular to the first direction, wherein the first sidewall comprises a first major surface and first protrusions protruding over the first major surface, and the second sidewall comprises a second major surface and second protrusions protruding over the second major surface, wherein the first major surface and the second major surface are flat surfaces;
epitaxial source/drain features interposing the channel region in the second direction;
an insulating layer disposed over the epitaxial source/drain features; and
a contact extending through the insulating layer to be electrically coupled to the epitaxial source/drain features, wherein an electrical conductivity of the contact is greater than an electrical conductivity of the epitaxial source/drain features.

10. The semiconductor device of claim 9, further comprising a third sidewall opposite the second sidewall, wherein the third sidewall comprises a third major surface and third protrusions protruding over the third major surface.

11. The semiconductor device of claim 10, wherein the first protrusions and the third protrusions are not symmetrical to each other.

12. The semiconductor device of claim 10, further comprising a fourth sidewall opposite the first sidewall, wherein the fourth sidewall is a flat surface.

13. The semiconductor device of claim 10, further comprising a gate dielectric layer conformally disposed over the first major surface and the first protrusions of the first sidewall and the second major surface and the second protrusions of the second sidewall.

14. The semiconductor device of claim 13, wherein the channel region comprises a plurality of nanostructures stacked vertically, wherein a gate spacer conformally disposed over the gate dielectric layer, wherein the gate spacer comprises a fifth sidewall that comprises a fourth major surface and fourth protrusions protruding over the fourth major surface, wherein the fourth major surface is aligned with a side surface of one of the nanostructures interfacing one of the epitaxial source/drain features.

15. A method for forming a semiconductor device, the method comprising:
forming a semiconductor strip over a substrate, wherein the semiconductor strip comprises first semiconductor layers and second semiconductor layers stacked alternatingly;
forming a dummy gate layer over the substrate and crossing over the semiconductor strip, wherein the forming the dummy gate layer comprises:
performing a first cycle multiple times and a second cycle at least one time, wherein the first cycle comprises a first deposition step and a first etch step, and the second cycle comprises a second deposition step and has no etch step, wherein the first deposition step and the second deposition step is operated at a first temperature; and
performing a third cycle multiple times and a fourth cycle at least one time, wherein the third cycle comprises a third deposition step and a second etch step, and the second cycle comprises a fourth deposition step and has no etch step, wherein the third deposition step and the fourth deposition step is operated at a second temperature greater than the first temperature;
forming gate spacers over opposite sidewalls of the dummy gate layer in a first direction;
etching the first semiconductor layers and the second semiconductor layers along the gate spacers to form first nanostructures and second nanostructures, respectively;
forming epitaxial source/drain features interposing the first nanostructures, wherein each of the epitaxial source/drain features comprises two layers that contain a same semiconductor material with different concentrations;
replacing the second nanostructures and the dummy gate layer with a gate electrode; and
forming an interlayer dielectric layer over the gate electrode and the epitaxial source/drain features, wherein the interlayer dielectric layer has a height thinner than a total height of the gate electrode.

16. The method of claim 15, wherein the first deposition step, the second deposition step, the third deposition step, and the fourth deposition step are low-pressure chemical vapor deposition.

17. The method of claim 15, wherein the first deposition step, the second deposition step, the third deposition step, and the fourth deposition step are operated in a pressure of about 0.1 torr to about 20 torr, wherein the first temperature is about 350 to about 500 degrees Celsius, and the second temperature is about 550 to about 800 degrees.

18. The method of claim 15, wherein the replacing the second nanostructures and the dummy gate layer with the gate electrode comprises:
replacing the second nanostructures with insulating nanostructures; and
replacing the insulating nanostructures and the dummy gate layer with the gate electrode.

19. The method of claim 15, wherein the first cycle is performed 5-7 times, and the second cycle is performed 3-5 times.

20. The method of claim 15, wherein the dummy gate layer has substantially no residual stress.
